(19) United States
(12) Patent Application Publication
(10) Pub. No.: US 2026/0206401 A1
(43) Pub. Date: Jul. 16, 2026

(54) LIGHT-EMITTING PANEL, BACKLIGHT MODULE, AND DISPLAY DEVICE

(71) Applicant: SHANGHAI TIANMA MICROELECTRONICS CO., LTD., Shanghai (CN)

(72) Inventors: Xiao YANG, Shanghai (CN); Lingyan LI, Shanghai (CN); Chunfeng LIU, Shanghai (CN); Xiongping LI, Shanghai (CN)

(73) Assignee: SHANGHAI TIANMA MICROELECTRONICS CO., LTD., Shanghai (CN)

(21) Appl. No.: 19/563,132

(22) Filed: Mar. 11, 2026

(30) Foreign Application Priority Data
Nov. 4, 2025 (CN) 202511605309.8

(51) Int. Cl. H10H 29/856; H10H 29/24

(52) U.S. Cl. CPC H10H 29/856; H10H 29/24

(57) ABSTRACT

Provided are a light-emitting panel, a backlight module, and a display device. The light-emitting panel includes a first light-emitting region and a second light-emitting region. The first light-emitting region is located on a side of the second light-emitting region facing an edge of the light-emitting panel. The first light-emitting region is provided with a plurality of first light-emitting elements. The light-emitting panel further includes a light emission adjustment structure. The light emission adjustment structure is located on the light emission side of the first light-emitting elements. The surface of the light emission adjustment structure facing the first light-emitting elements is non-planar.

### CROSS-REFERENCE TO RELATED APPLICATION

This application claims priority to Chinese Patent Application No. 202511605309.8, filed on Nov. 4, 2025, the disclosure of which is incorporated herein by reference in its entirety.

### TECHNICAL FIELD

The present disclosure relates to the field of display technology and, in particular, to a light-emitting panel, a backlight module, and a display device.

### BACKGROUND

With the continuous development of display technology, devices with the display function have been widely used in people's production and life activities. Devices with the display function include light-emitting panels. A light-emitting panel includes multiple light-emitting elements. The light-emitting function of the light-emitting panel is implemented by driving the light-emitting elements to emit light. However, in the related art, the brightness of the edge region of the light-emitting panel is weaker than the brightness of the central region, thus easily causing uneven display of the light-emitting panel.

### SUMMARY

Embodiments of the present application provide a light-emitting panel, a backlight module, and a display device.

In a first aspect, an embodiment of the present application provides a light-emitting panel. The light-emitting panel includes a first light-emitting region and a second light-emitting region. The first light-emitting region is located on a side of the second light-emitting region facing an edge of the light-emitting panel. The first light-emitting region is provided with a plurality of first light-emitting elements.

The light-emitting panel further includes a light emission adjustment structure. The light emission adjustment structure is located on a light emission side of the plurality of first light-emitting elements. A surface of the light emission adjustment structure facing the plurality of first light-emitting elements is non-planar.

In a second aspect, an embodiment of the present application provides a backlight module. The backlight module includes a light-emitting panel. The light-emitting panel includes a first light-emitting region and a second light-emitting region. The first light-emitting region is located on a side of the second light-emitting region facing an edge of the light-emitting panel. The first light-emitting region is provided with a plurality of first light-emitting elements. The light-emitting panel further includes a light emission adjustment structure. The light emission adjustment structure is located on a light emission side of the plurality of first light-emitting elements. A surface of the light emission adjustment structure facing the plurality of first light-emitting elements is non-planar.

In a third aspect, an embodiment of the present application provides a display device. The display device includes a backlight module and a display panel located on a side of a light emission surface of the backlight module. The backlight module includes a light-emitting panel. The light-emitting panel includes a first light-emitting region and a second light-emitting region. The first light-emitting region is located on a side of the second light-emitting region facing an edge of the light-emitting panel. The first light-emitting region is provided with a plurality of first light-emitting elements. The light-emitting panel further includes a light emission adjustment structure. The light emission adjustment structure is located on a light emission side of the plurality of first light-emitting elements. A surface of the light emission adjustment structure facing the plurality of first light-emitting elements is non-planar.

### BRIEF DESCRIPTION OF DRAWINGS

To illustrate solutions in embodiments of the present application more clearly, the drawings used in description of the embodiments of the present application are described briefly hereinafter. Apparently, the drawings described hereinafter only illustrate part of embodiments of the present application, and those skilled in the art may obtain other drawings based on the contents and drawings described in the embodiments of the present application on the premise that no creative work is done.

FIG. 1 is a structural view of a light-emitting panel according to an embodiment of the present application.

FIG. 2 is the first sectional view taken along line A-A' of FIG. 1.

FIG. 3 is the second sectional view taken along line A-A' of FIG. 1.

FIG. 4 is the third sectional view taken along line A-A' of FIG. 1.

FIG. 5 is a view of the preparation process of a light-emitting panel according to an embodiment of the present application.

FIG. 6 is an enlarged view of a first light emission adjustment structure of the first type according to an embodiment of the present application.

FIG. 7 is an enlarged view of a first light emission adjustment structure of the second type according to an embodiment of the present application.

FIG. 8 is an enlarged view of a first light emission adjustment structure of the third type according to an embodiment of the present application.

FIG. 9 is an enlarged view of a first light emission adjustment structure of the fourth type according to an embodiment of the present application.

FIG. 10 is an enlarged view of a first light emission adjustment structure of the fifth type according to an embodiment of the present application.

FIG. 11 is the fourth sectional view taken along line A-A' of FIG. 1.

FIG. 12 is a view of the preparation process of another light-emitting panel according to an embodiment of the present application.

FIG. 13 is an enlarged view of a second light emission adjustment structure of the first type according to an embodiment of the present application.

FIG. 14 is a top view of a first light entry adjustment surface portion in the second light emission adjustment structure of FIG. 13.

FIG. 15 is a top view of a first light emission adjustment surface portion in the second light emission adjustment structure of FIG. 13.

FIG. 16 is an enlarged view of a second light emission adjustment structure of the second type according to an embodiment of the present application.

FIG. 17 is the fifth sectional view taken along line A-A' of FIG. 1.

FIG. 18 is a structural view of a light emission panel in the related art.

FIG. 19 is a view of a drive signal supplied to a light-emitting element by a driving substrate in the related art.

FIG. 20 is a view of a drive signal supplied to a light-emitting element by a driving substrate in the present application.

FIG. 21 is a structural view of a backlight module according to an embodiment of the present application.

FIG. 22 is a structural view of a display device according to an embodiment of the present application.

FIG. 23 is a sectional view taken along line B-B' of FIG. 22.

### DETAILED DESCRIPTION

The present application is further described in detail in conjunction with the drawings and the embodiments. It is to be understood that the embodiments set forth below are intended to illustrate and not to limit the present application. Additionally, it is to be noted that for ease of description, only part, not all, of structures related to the present application are illustrated in the drawings.

In the description of the present application, unless otherwise expressly specified and limited, the term "connected to each other", "connected", or "fixed" is to be construed in a broad sense, for example, as fixedly connected, detachably connected, or integrated; mechanically connected or electrically connected; directly connected to each other or indirectly connected to each other via an intermediary; or internally connected or interactional between two components. For those skilled in the art, the preceding term in the present disclosure can be construed depending on specific contexts.

In the present application, unless otherwise expressly specified and limited, when a first feature is described as "above" or "below" a second feature, the first feature and the second feature may be in direct contact, or be in contact via another feature between the two features. Moreover, when the first feature is described as “on”, “above” or “over” the second feature, the first feature is right on, above or over the second feature or the first feature is obliquely on, above or over the second feature, or the first feature is simply at a higher level than the second feature. When the first feature is described as “under”, “below” or “underneath” the second feature, the first feature is right under, below or underneath the second feature or the first feature is obliquely under, below or underneath the second feature, or the first feature is simply at a lower level than the second feature.

In the description of this embodiment, the orientation or position relationships indicated by terms “above”, “below”, “left”, “right” and the like are based on the orientation or position relationships shown in the drawings, merely for facilitating description of the present disclosure and simplifying operation, and these relationships do not indicate or imply that the referred device or element has a specific orientation and is constructed and operated in a specific orientation, and thus it is not to be construed as limiting the present application. Moreover, the terms "first" and "second" in the specification are only used for descriptive purposes and have no special meanings.

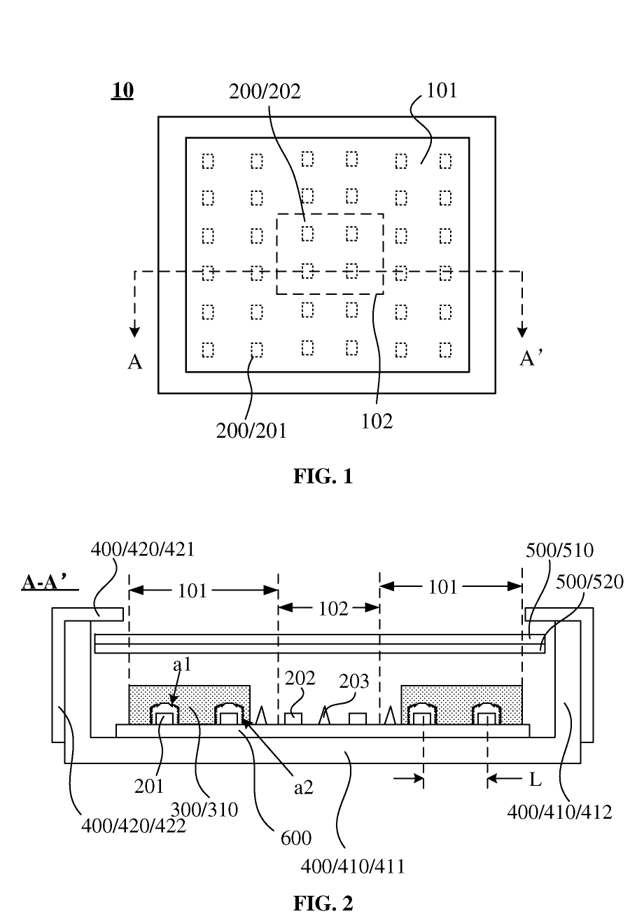

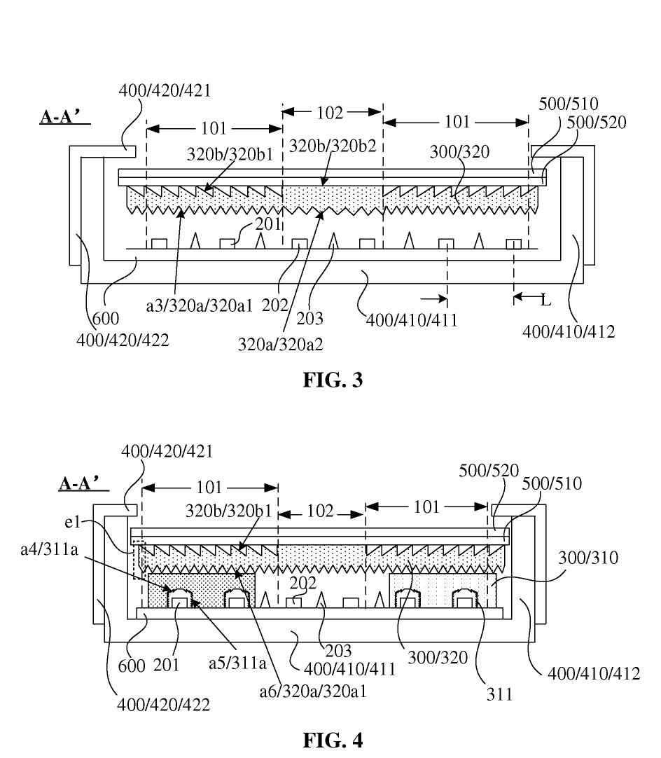

FIG. 1 is a structural view of a light-emitting panel according to an embodiment of the present application. FIG. 2 is the first sectional view taken along line A-A' of FIG. 1. FIG. 3 is the second sectional view taken along line A-A' of FIG. 1. FIG. 4 is the third sectional view taken along line A-A' of FIG. 1. Referring to FIGS. 1 to 4, an embodiment of the present application provides a light-emitting panel 10. The light-emitting panel 10 includes a first light-emitting region 101 and a second light-emitting region 102. The first light-emitting region 101 is located on a side of the second light-emitting region 102 facing an edge of the light-emitting panel 10. The first light-emitting region 101 is provided with a plurality of first light-emitting elements 201. The light-emitting panel 10 further includes a light emission adjustment structure 300. The light emission adjustment structure 300 is located on the light emission side of the first light-emitting elements 201. The surface of the light emission adjustment structure 300 facing the first light-emitting elements 201 is non-planar.

Referring to FIG. 1, the light-emitting panel 10 provided in the embodiment of the present application includes a plurality of light-emitting elements 200. The light-emitting function of the light-emitting panel 10 can be implemented by driving the plurality of light-emitting elements 200 to emit light. Further, referring to FIG. 1, the light-emitting panel 10 includes the first light-emitting region 101 and the second light-emitting region 102 that divide the light-emitting panel 10 into regions. The first light-emitting region 101 is closer to the edge of the light-emitting panel 10 than the second light-emitting region 102. Therefore, the first light-emitting region 101 may be understood as a light-emitting region facing the edge of the light-emitting panel 10, and the second light-emitting region 102 may be understood as a light-emitting region close to the center of the light-emitting panel 10. In an embodiment, referring to FIG. 1, a light-emitting element 200 disposed in the first light-emitting region 101 is a first light-emitting element 201. In the embodiments of the present disclosure, a light-emitting element 200 may be a light-emitting element that emits white light, blue light, or purple light. The light-emitting color of the light-emitting element 200 may be selected according to different light-emitting panels 10, which is not specifically limited in the present application.

In an embodiment, a first light-emitting element 201 disposed in the first light-emitting region 101 is closer to the edge of the light-emitting panel 10 than a light-emitting element 200 disposed in the second light-emitting region 102. Therefore, a difference in brightness exists between the first light-emitting region 101 and the second light-emitting region 102. In an embodiment, the brightness difference between the first light-emitting region 101 and the second light-emitting region 102 may be understood as follows. On one hand, since the first light-emitting element 201 is closer to the edge region of the light-emitting panel 10, the number of light-emitting elements 200 disposed on a side of the first light-emitting element 201 facing the edge of the light-emitting panel 10 is small, or no additional light-emitting element 200 is provided. Therefore, the number of light-emitting elements 200 that may perform mutual brightness compensation around the first light-emitting element 201 is relatively small, so that the brightness provided in the first light-emitting region 101 is weaker than the brightness provided in the second light-emitting region 102. On the other hand, the arrangement position of the first light-emitting element 201 is closer to the edge region of the light-emitting panel 10, so that part of the light emitted from the first light-emitting element 201 is emitted in a gap at the edge of the light-emitting panel 10 that the first light-emitting element 201 is close to. The gap at the edge may be understood as a boundary between a light-emitting region of the light-emitting panel 10 and a light non-emitting region of the light-emitting panel 10. The edge gap of the light-emitting panel 10 does not belong to an effective light-emitting region of the light-emitting panel 10, thus reducing the overall light emission efficiency of the first light-emitting element 201, making the brightness provided in the first light-emitting region 101 weaker than the brightness provided in the second light-emitting region 102, and causing light leakage in the edge region of the light-emitting panel 10.

Further, in order to ensure that the brightness of the first light-emitting region 101 is similar to the brightness of the second light-emitting region 102, the light-emitting panel 10 provided in the embodiment of the present application further includes the light emission adjustment structure 300 to ensure the light-emitting evenness of the light-emitting panel 10 and avoid light leakage in the gap at the edge of the light-emitting panel 10. Referring to FIGS. 2 to 4, the light emission adjustment structure 300 is disposed at least in the first light-emitting region 101. The light emission adjustment structure 300 adjusts the light emitted from the first light-emitting elements 201, thus improving the brightness of the first light-emitting region 101, ensuring that the first light-emitting region 101 is similar to the brightness of the second light-emitting region 102, and thus ensuring the overall light emission uniformity of the light-emitting panel 10. Moreover, the light emission adjustment structure 300 may also avoid or reduce the transmission of the light emitted from the first light-emitting elements 201 to the edge of the light-emitting panel 10, reduce light leakage in the edge region of the light-emitting panel 10, and ensure the overall light-emitting effect of the light-emitting panel 10.

In an embodiment, referring to FIGS. 2 to 4, the surface of the light emission adjustment structure 300 facing the first light-emitting elements 201 is non-planar. The light transmission path may be adjusted when the light emitted from the first light-emitting elements 201 is transmitted to the non-planar surface of the light emission adjustment structure 300, thus implementing the adjustment of the light emission of the first light-emitting elements 201 and ensuring that the light emitted from the first light-emitting elements 201 is in the light emission direction of the light-emitting elements 200 as much as possible, thus improving the light-emitting intensity of the first light-emitting region 101, ensuring that the brightness of the first light-emitting region 101 is similar to the brightness of the second light-emitting region 102, ensuring the overall light-emitting effect of the light-emitting panel 10, and preventing light from leaking out from the gap at the edge of the light-emitting panel 10. Exemplarily, referring to FIG. 2, regions indicated by arrows a1 and a2 in FIG. 2 may be understood as non-planar positions of the light emission adjustment structure 300. Referring to FIG. 3, a region indicated by arrow a3 in FIG. 3 may be understood as a non-planar position of the light emission adjustment structure 300. Referring to FIG. 4, regions indicated by arrows a4, a5, and a6 in FIG. 3 may be understood as non-planar positions of the light emission adjustment structure 300. It is to be noted that there are various arrangement modes of the light emission adjustment structure 300. FIGS. 2 to 4 are used for illustration. Moreover, in FIGS. 2 to 4, in order to distinguish the difference between the light emission adjustment structure 300 and other structures, the light emission adjustment structure 300 is filled with a pattern in the drawings provided in embodiments of the present application.

In general, in the light-emitting panel 10 according to this embodiment of the present application, the light emission adjustment structure 300 is disposed in the first light-emitting region 101, and the surface of the light emission adjustment structure 300 facing the first light-emitting elements 201 includes a non-planar region. The light emitted from the first light-emitting elements 201 may be adjusted by the non-planar surface, improving the brightness of the first light-emitting region 10, reducing or avoiding light leakage at the gap at the edge of the light-emitting panel 10, ensuring the brightness evenness of the first light-emitting region 101 and the second light-emitting region 102, reducing the color difference between different regions of the light-emitting panel 10, and ensuring that the brightness of different regions of the light-emitting panel 10 is even.

In the embodiments of the present disclosure, referring to FIGS. 2 to 4, the light-emitting panel 10 may further include a bezel structure 400 for supporting and protecting the overall structure. In an embodiment, the bezel structure 400 includes a support bezel 410 and a frame bezel 420. The support bezel 410 is used for ensuring the stability of the overall structure. The frame bezel 420 is used for further protecting the overall structure. The support bezel 410 includes a first support unit 411 and a second support unit 412 connected to each other. The frame bezel 420 includes a first frame unit 421 and a second frame unit 422 connected to each other. The first support unit 411 is perpendicular to the light emission direction of the light-emitting elements 200. The second support unit 412 is disposed in the light emission direction of the light-emitting elements 200. The first frame unit 421 is perpendicular to the light emission direction of the light-emitting elements 200 and is located in the region of the first support unit 411 away from the center of the light-emitting panel 10. The second frame unit 422 is disposed in the light emission direction of the light-emitting elements 200 and is disposed on a side of the second support unit 412 facing away from the light-emitting elements 200.

In the embodiments of the present disclosure, the light-emitting panel 10 further includes an optical film 500 disposed on the light emission side of the light-emitting elements 200. The optical film 500 may include, for example, a diffusion layer, a brightness enhancement film, or a color conversion layer. This embodiment of the present application does not specifically limit layers included in the optical film 500. The bezel frame 420 may also serve as a limit structure of the optical film 500, preventing the optical film 500 from being warped in a mechanical test and ensuring the stability of the overall structure.

In the embodiments of the present disclosure, the light-emitting elements in the light-emitting panel may include different light-emitting surface types. For example, a light-emitting element may be of a light-emitting surface type of a Lambertian body or of a light-emitting surface type of a bat wing. The present application does not specifically limit the specific light-emitting model of a light-emitting element.

Above all, this embodiment of the present application provides a light-emitting panel. The light-emitting panel is provided with the light emission adjustment structure. The light-emitting adjustment structure may adjust the light emission of the first light-emitting elements located in the first light-emitting region, thus improving the light emission effect of the first light-emitting region. Further, the surface of the light emission adjustment structure facing the first light-emitting elements is non-planar. The light emission of the first light-emitting elements is adjusted by using the non-planar structure, thereby implementing the adjustment of the brightness of the first light-emitting region, preventing light from being emitted from the gap at the edge of the light-emitting panel, ensuring the overall light-emitting uniformity of the light-emitting panel, and ensuring the overall light-emitting effect of the light-emitting panel.

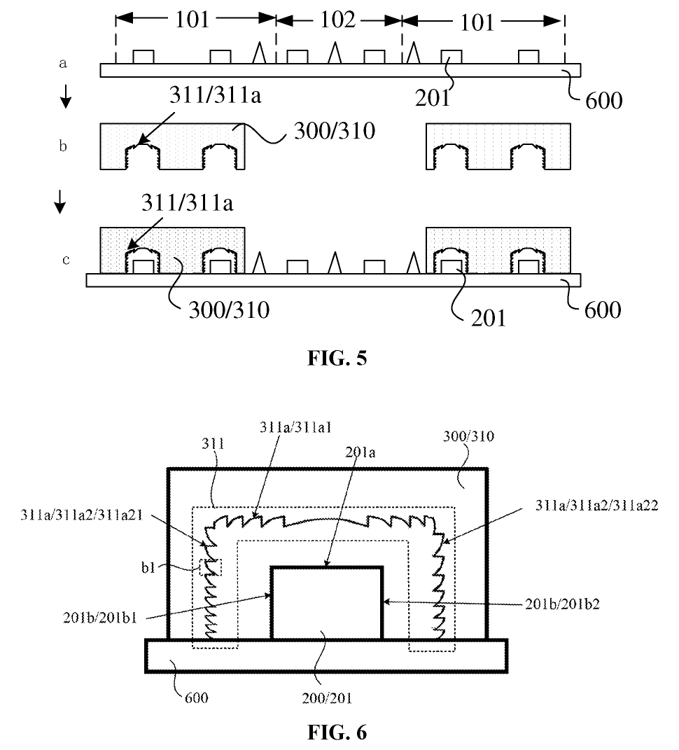

On the basis of the preceding embodiments, FIG. 5 is a view of the preparation process of a light-emitting panel according to an embodiment of the present application. FIG. 6 is an enlarged view of a first light emission adjustment structure of the first type according to an embodiment of the present application. With continued reference to FIGS. 2, 4, 5, and 6, the light emission adjustment structure 300 includes a first light emission adjustment structure 310. The first light emission adjustment structure 310 includes a plurality of first avoidance recesses 311. A first avoidance recess 311 covers at least one first light-emitting element 201.

In an embodiment, as shown in FIGS. 2, 4, 5, and 6, the light emission adjustment structure 300 includes the first light emission adjustment structure 310. The first light emission adjustment structure 310 includes a plurality of first avoidance recesses 311. A first avoidance recess 311 covers at least one first light-emitting element 201. FIGS. 2, 4, and 6 illustrate an example that one first avoidance recess 311 covers one first light-emitting element 201. The number of first light-emitting elements 201 covered by a first avoidance recess 311 may be adaptively adjusted according to actual needs. For example, the arrangement size of a first avoidance recess 311 is increased to enable it to accommodate more first light-emitting elements 201, which is not specifically limited in the present application.

Further, referring to FIG. 6, the first avoidance recess 311 covers the first light-emitting element 201. The surface of the first avoidance recess 311 facing the first light-emitting element 201 is used for adjusting the light emitted from the first light-emitting element 201 so that the surface of the first avoidance recess 311 facing the first light-emitting element 201 may be non-planar, thus ensuring that the light-emitting intensity of the first light-emitting region 101 is increased.

Further, referring to FIG. 5, the preparation process of the light-emitting panel 10 may be as follows: First, referring to step a in FIG. 5, the first light-emitting elements 201 are prepared in the first light-emitting region 101; then referring to step b in FIG. 5, the light emission adjustment structure 300 is provided, and the surface of the light emission adjustment structure 300 is non-planar; finally, referring to step c in FIG. 5, the light emission adjustment structure 300 is placed on the light emission side of the first light-emitting elements 201, and the non-planar surface of the light emission adjustment structure 300 is placed toward a side of the first light-emitting elements 201. In this case, it may be understood that the light emission adjustment structure 300 is a structure prepared by another process first, such as injection molding or hot pressing process. After the first light emission adjustment structure 310 is prepared, the first light emission adjustment structure 310 is placed on a side of the first light-emitting elements 201. Therefore, when the surface of the light emission adjustment structure 300 is designed to be non-planar, the related preparation process does not cause damage to the light-emitting elements 200 and thus does not affect the light-emitting effect of the light-emitting panel 10. Therefore, the first light-emitting elements 201 are not damaged by providing the first avoidance recesses 311 in the first light emission adjustment structure 310. Moreover, the arrangement of the first avoidance recesses 311 in the first light emission adjustment structure 310 may also improve the alignment accuracy of moving the first light emission adjustment structure 310 to the first light-emitting elements 201, reduce the transfer difficulty of the first light emission adjustment structure 310, and ensure that the preparation of the light-emitting panel 10 is more reliable.

In an embodiment, referring to FIG. 6, the first avoidance recess 311 includes an inner surface 311a. At least part of the inner surface 311a is provided with a Fresnel lens.

Referring to FIG. 6, the first avoidance recess 311 covers the first light-emitting element 201. The light emitted from the first light-emitting element 201 is transmitted to the inner surface 311a of the first avoidance recess 311. Therefore, the inner surface 311a of the first avoidance recess 311 is used for adjusting the light emitted from the first light-emitting element 201. In an embodiment, in order to ensure the adjustment of the light emitted from the first light-emitting element 201, the inner surface 311a of the first avoidance recess 311 is designed to be non-planar. Exemplarily, referring to FIG. 6, at least part of the inner surface 311a is provided with the Fresnel lens.

A Fresnel lens, also referred to as a threaded lens, is an optical element that divides the curved surface of a traditional lens into a series of concentric rings (referred to as Fresnel rings or Fresnel belts) and flattens them onto the same plane, thereby implementing the adjustment of light through the principle of refraction. Compared with a traditional lens, the Fresnel lens has the advantages of being thinner, lighter, and more cost-effective. The non-planar inner surface 311a is designed as the Fresnel lens. The light emitted from the first light-emitting element 201 may be concentrated and emitted by using the light convergence effect of the Fresnel lens, thereby improving the brightness of the first light-emitting region 101, preventing the light emitted from the first light-emitting element 201 from being diverted to the surroundings, and avoiding light leakage at the gap at the edge of the light-emitting panel 10.

With continued reference to FIG. 6, the light-emitting panel 10 further includes a driving substrate 600. The first light-emitting element 201 is disposed on a side of the driving substrate 600 and is electrically connected to the driving substrate 600. The first light-emitting element 201 includes an upper light-emitting surface 201a. The upper light-emitting surface 201a is a light-emitting surface of the first light-emitting element 201 facing away from the driving substrate 600. The inner surface 311a includes an upper inner surface 311a1 located on a side of the upper light-emitting surface 201a facing away from the driving substrate 600. The upper inner surface 311a1 is provided with a first Fresnel lens.

In an embodiment, referring to FIGS. 2 to 4 and 6, the light-emitting panel 10 includes the driving substrate 600 as a carrier substrate of the light-emitting elements 200. Further, a driving circuit electrically connected to a light-emitting element 200 is disposed above or inside the driving substrate 600 for supplying a light-emitting drive signal to the light-emitting element 200, thereby driving the light-emitting element 200 to emit light.

Further, referring to FIG. 6, the first light-emitting element 201 includes the upper light-emitting surface 201a. The upper light-emitting surface 201a is the light-emitting surface of the first light-emitting element 201 facing away from the driving substrate 600. In an embodiment, regarding the arrangement position, the upper light-emitting surface 201a may be understood as a light-emitting surface corresponding to the light emission side of the first light-emitting element 201. Therefore, the upper light-emitting surface 201a may also be understood as a main light-emitting surface of the first light-emitting element 201a. The first light emission adjustment structure 310 may adjust the light emitted from the upper light-emitting surface 201a, improve the light emission efficiency of the first light-emitting element 201, improve the brightness of the first light-emitting region 101, and prevent the light emitted from the first light-emitting element 201 from leaking out from the gap at the edge of the light-emitting panel 10.

In an embodiment, in the first avoidance recess 311, the inner surface 311a includes the upper inner surface 311a1 located on a side of the upper light-emitting surface 201a facing away from the driving substrate 600. The upper inner surface 311a1 is provided with the first Fresnel lens. In combination with the light adjustment effect of a Fresnel lens, the upper inner surface 311a1 may effectively adjust the light emitted from the upper light-emitting surface 201a. In an embodiment, the upper inner surface 311a1 may converge the light emitted from the first light-emitting element 201, improving the brightness of the first light-emitting region 101, reducing the brightness difference between the first light-emitting region 101 and the second light-emitting region 102, ensuring the light-emitting evenness of the light-emitting panel 10, effectively preventing the light emitted from the first light-emitting element 201 from being emitted from the gap at the edge of the light-emitting panel 10, and avoiding light leakage at the gap at the edge of the light-emitting panel 10.

With continued reference to FIG. 6, the first light-emitting element 201 further includes a side light-emitting surface 201b. The side light-emitting surface 201b is connected to the upper light-emitting surface 201a. The inner surface 311a further includes a side inner surface 311a2. The side inner surface 311a2 is connected to the upper inner surface 311a1 and is located on a side of the side light-emitting surface 201b. The side inner surface 311a2 is provided with a second Fresnel lens.

Further, referring to FIG. 6, the first light-emitting element 201 further includes the side light-emitting surface 201b. The side light-emitting surface 201b and the main light-emitting surface 201a are both light-emitting surfaces of the first light-emitting element 201. Moreover, in order to better adjust the light emitted from the first light-emitting element 201, the first light emission adjustment structure 310 may adjust both the light emitted from the upper light-emitting surface 201a and the light emitted from the side light-emitting surface 201b, thus further improving the light-emitting efficiency of the first light-emitting element 201, better ensuring the brightness of the first light-emitting region 101, and preventing the light emitted from the first light-emitting element 201 from leaking out from the edge of the light-emitting panel 10.

In an embodiment, referring to FIG. 6, the inner surface 311a of the first avoidance recess 311 further includes the side inner surface 311a2. The side inner surface 311a2 is connected to the upper inner surface 311a1 and located on a side of the side light-emitting surface 201b. The side inner surface 311a2 is provided with the second Fresnel lens. In combination with the light adjustment effect of a Fresnel lens, the second Fresnel lens in the side inner surface 311a2 may effectively adjust the light emitted from the side light-emitting surface 201b. In an embodiment, both the upper inner surface 311a1 and the side inner surface 311a2 may converge light emitted from the first light-emitting element 201, further improving the brightness of the first light-emitting region 101, reducing the brightness difference between the first light-emitting region 101 and the second light-emitting region 102, ensuring the light-emitting evenness of the light-emitting panel 10, more effectively preventing the light emitted from the first light-emitting element 201 from leaking out from the gap at the edge of the light-emitting panel 10, and avoiding light leakage at the gap at the edge of the light-emitting panel 10.

FIG. 7 is an enlarged view of a first light emission adjustment structure of the second type according to an embodiment of the present application. Referring to FIGS. 6 and 7, the side light-emitting surface 201b includes a first side light-emitting surface 201b1 and a second side light-emitting surface 201b2. The first side light-emitting surface 201b1 is located on a side of the second side light-emitting surface 201b2 facing the edge of the light-emitting panel 10. The side inner surface 311a2 includes a first side inner surface 311a21 and a second side inner surface 311a22. The first side inner surface 311a21 is located on a side of the first side light-emitting surface 201b1 facing the edge of the light-emitting panel 10. The second side inner surface 311a22 is located on a side of the second side light-emitting surface 201b2 facing away from the edge of the light-emitting panel 10. The first side inner surface 311a21 and the second side inner surface 311a22 are each provided with a second Fresnel lens. The distribution density of Fresnel rings in a second Fresnel lens on the first side inner surface 311a21 is greater than or equal to the distribution density of Fresnel rings in a second Fresnel lens on the second side inner surface 311a22.

In an embodiment, referring to FIGS. 6 and 7, in the first light-emitting element 201, the side light-emitting surface 201b includes the first side light-emitting surface 201b1 and the second side light-emitting surface 201b2. The first side light-emitting surface 201b1 is located on a side of the second side light-emitting surface 201b2 facing the edge of the light-emitting panel 10. The adjustment intensity of the light emitted from the first side light-emitting surface 201b1 may be set to be greater than or equal to the adjustment intensity of the light emitted from the second side light-emitting surface 201b2 so as to reduce or avoid the light emitted from the first light-emitting element 201 and transmitted to the gap at the edge of the light-emitting panel 10 and avoid light leakage at the gap at the edge of the light-emitting panel 10.

On the inner surface 311a of the first avoidance recess 311, the side inner surface 311a2 includes the first side inner surface 311a21 and the second side inner surface 311a22. The first side inner surface 311a21 is located on a side of the first side light-emitting surface 201b1 facing the edge of the light-emitting panel 10. Referring to FIGS. 6 and 7, the first side inner surface 311a21 may adjust the light emitted from the first side light-emitting surface 201b1. The second side inner surface 311a22 may adjust the light emitted from the second side light-emitting surface 201b2. In an embodiment, the first side inner surface 311a21 and the second side inner surface 311a22 are each provided with a second Fresnel lens. The distribution density of Fresnel rings in the second Fresnel lens on the first side inner surface 311a21 and the distribution density of Fresnel rings in the second Fresnel lens on the second side inner surface 311a22 may be adjusted in order to implement that the adjustment intensity of the light emitted from the first side light-emitting surface 201b1 is greater than or equal to the adjustment intensity of the light emitted from the second side light-emitting surface 201b2.

In an embodiment, referring to FIG. 7, the distribution density of Fresnel rings in the second Fresnel lens on the first side inner surface 311a21 is equal to the distribution density of Fresnel rings in the second Fresnel lens on the second side inner surface 311a22. Such an arrangement may ensure the effective adjustment of the light emitted from the first side light-emitting surface 201b1 and the light emitted from the second side light-emitting surface 201b2, reduce the design difficulty of the first light emission adjustment structure 310, and reduce the process preparation difficulty of the first light emission adjustment structure 310.

In an embodiment, referring to FIG. 6, the distribution density of the Fresnel rings in the second Fresnel lens on the first side inner surface 311a21 is greater than the distribution density of Fresnel rings in the second Fresnel lens on the second side inner surface 311a22. Such an arrangement may implement that the adjustment intensity of the light emitted from the first side light-emitting surface 201b1 is greater than or equal to the adjustment intensity of the light emitted from the second side light-emitting surface 201b2, ensure the light adjustment effect on the first light-emitting element 201, and ensure a better light convergence effect on the light emitted from the first light-emitting element 201.

It is to be noted that in FIGS. 6 and 7, the distribution density of Fresnel rings in each second Fresnel lens may be expressed by the number of Fresnel rings installed per unit area. A region denoted by b1 in the figures represents one Fresnel ring. For example, in FIG. 6, the number of Fresnel rings per unit area in the second Fresnel lens on the first side inner surface 311a21 is greater than the number of Fresnel rings per unit area in the second Fresnel lens on the second side inner surface 311a22. For example, in FIG. 7, the number of Fresnel rings per unit area in the second Fresnel lens on the first side inner surface 311a21 is equal to the number of Fresnel rings per unit area in the second Fresnel lens on the second side inner surface 311a22. The distribution density of Fresnel rings may also be reflected by the size of a Fresnel ring or the like, which is not specifically limited in the present application.

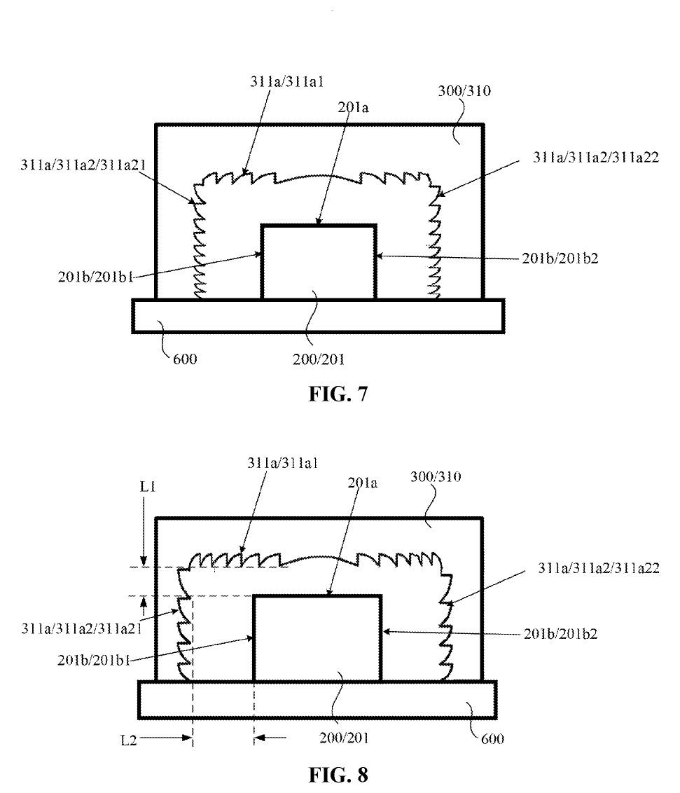

FIG. 8 is an enlarged view of a first light emission adjustment structure of the third type according to an embodiment of the present application. The distribution density of Fresnel rings in the first Fresnel lens is greater than or equal to the distribution density of Fresnel rings in a second Fresnel lens.

In an embodiment, in the first light-emitting element 201, the upper light-emitting surface 201a and the side light-emitting surface 201b are compared with each other. The upper light-emitting surface 201a may be understood as a main light-emitting surface of the first light-emitting element 201. The side light-emitting surface 201b may be understood as a secondary light-emitting surface of the first light-emitting element 201. Therefore, in order to implement the efficient adjustment of the light emission of the first light-emitting element 201, the first light emission adjustment structure 310 better converges the light emitted from the first light-emitting element 201. The light emission of the upper light-emitting surface 201a may be preferentially adjusted; alternatively, the light emission from the light-emitting surface 201a may be adjusted to a greater extent. Therefore, the distribution density of Fresnel rings in the first Fresnel lens may be adjusted to be greater than or equal to the distribution density of Fresnel rings in the second Fresnel lens. Exemplarily, referring to FIG. 8, by way of example, the number of Fresnel rings per unit area in the first Fresnel lens is greater than the number of Fresnel rings per unit area in the second Fresnel lens so that the distribution density of Fresnel rings in the first Fresnel lens is greater than the distribution density of Fresnel rings in the second Fresnel lens, better ensuring the light convergence adjustment effect on the light emitted from the first light-emitting element 201. In the embodiments of the present disclosure, in order to ensure the structural regularity of the first light emission adjustment structure 310, the number of Fresnel rings per unit area in the first Fresnel lens may be adjusted to be equal to the number of Fresnel rings per unit area in the second Fresnel lens, thereby ensuring the light concentration adjustment effect on the light emitted from the first light-emitting element 201 and reducing the process preparation difficulty of the first light emission adjustment structure 310.

With continued reference to FIG. 8, the minimum distance between the upper light-emitting surface 201a and the upper inner surface 311a1 is less than or equal to the minimum distance between the side light-emitting surface 201b and the side inner surface 311a22.

The less the relative minimum distance between the first avoidance recess 311 and the first light-emitting element 201 is, the more obvious the light concentration adjustment effect on the light emitted from the first light-emitting element 201 by a Fresnel lens in the first avoidance recess 311 is. In an embodiment, in the first light-emitting element 201, the upper light-emitting surface 201a and the side light-emitting surface 201b are compared with each other. The upper light-emitting surface 201a may be understood as a main light-emitting surface of the first light-emitting element 201. The side light-emitting surface 201b may be understood as a secondary light-emitting surface of the first light-emitting element 201. Therefore, in order that the first light emission adjustment structure 310 implements the light emission adjustment effect on the first light-emitting element 201 and better converge the light emitted from the first light-emitting element 201, the minimum distance between the upper light-emitting surface 201a and the upper inner surface 311a1 may be adjusted to be less than or equal to the minimum distance between the side light-emitting surface 201b and the side inner surface 311a22. Exemplarily, referring to FIG. 8, L1 denotes the minimum distance between the light-emitting surface 201a and the upper inner surface 311a1. L2 denotes the minimum distance between the side light-emitting surface 201b and the side inner surface 311a22. It may be adjusted that L1 ≥ L2. Such an arrangement may also represent diversified arrangement manners of the first light emission adjustment structure 310.

With continued reference to FIGS. 6 to 8, the first Fresnel lens and the second Fresnel lens are disposed independently.

In the first light-emitting element 201, the main light-emitting surface 201a and the side light-emitting surface 201b have different light emission angles. Therefore, the first Fresnel lens disposed on the upper inner surface 311a1 and the second Fresnel lens disposed on the side inner surface 311a2 may be disposed independently. The first Fresnel lens and the second Fresnel lens allow for independent light emission modulation, ensuring a better light convergence effect on the light emitted from the first light-emitting element 201 and through the first light emission adjustment structure 310.

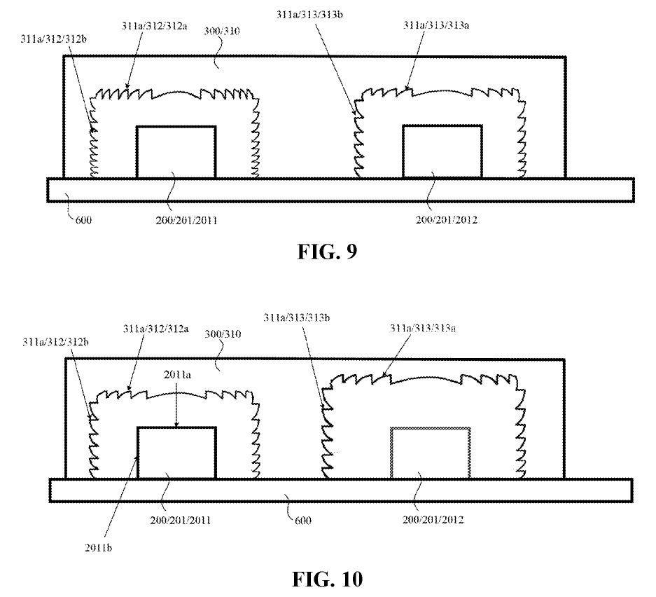

FIG. 9 is an enlarged view of a first light emission adjustment structure of the fourth type according to an embodiment of the present application. Referring to FIG. 9, the plurality of first light-emitting elements 201 include a first light-emitting sub-element 2011 and a second light-emitting sub-element 2012. The first light-emitting sub-element 2011 is located on a side of the second light-emitting sub-element 2012 facing the edge of the light-emitting panel 10. The first light emission adjustment structure 310 includes a first inner surface 312 and a second inner surface 313, where the first inner surface 312 at least partially covers the first light-emitting sub-element 2011, and the second inner surface 313 at least partially covers the second light-emitting sub-element 2012. The first inner surface 312 includes a first upper inner surface 312a and a third side inner surface 312b. The second inner surface 313 includes a second upper inner surface 313a and a fourth side inner surface 313b. The distribution density of Fresnel rings in a first Fresnel lens on the first upper inner surface 312a is greater than or equal to the distribution density of Fresnel rings in a first Fresnel lens on the second upper inner surface 313a. Moreover/alternatively, the distribution density of Fresnel rings in a second Fresnel lens on the third side inner surface 312b is greater than or equal to the distribution density of Fresnel rings in a second Fresnel lens on the fourth side inner surface 313b.

Referring to FIG. 9, the plurality of first light-emitting elements 201 are disposed in the first light-emitting region 101. The first light-emitting elements 201 include the first light-emitting sub-element 2011 and the second light-emitting sub-element 2012. The arrangement position of the first light-emitting sub-element 2011 is different from the arrangement position of the second light-emitting sub-element 2012. In an embodiment, the first light-emitting sub-element 2011 is located on a side of the second light-emitting sub-element 2012 facing the edge of the light-emitting panel 10.

Further, referring to FIG. 9, the first light emission adjustment structure 310 may cover the first light-emitting sub-element 2011 and the second light-emitting sub-element 2012. In an embodiment, the first light emission adjustment structure 310 includes the first inner surface 312 and the second inner surface 313, where the first inner surface 312 at least partially covers the first light-emitting sub-element 2011, and the second inner surface 313 at least partially covers the second light-emitting sub-element 2012. Therefore, the first inner surface 312 may adjust the light emitted from the first light-emitting sub-element 2011, ensuring that the light emitted from the first light-emitting sub-element 2011 is more converged after passing through the first light emission adjustment structure 310. The second inner surface 313 may adjust the light emitted from the second light-emitting sub-element 2012, ensuring that the light emitted from the second light-emitting sub-element 2012 is more converged after passing through the first light emission adjustment structure 310. With the arrangement of the first inner surface 312 and the second inner surface 313, the first light emission adjustment structure 310 may effectively modulate the light emitted from the plurality of first light-emitting elements 201, improving the brightness of the first light-emitting region 101 and avoiding light leakage at the gap at the edge of the light-emitting panel 10.

In an embodiment, referring to FIG. 9, the first inner surface 312 includes the first upper inner surface 312a and the third side inner surface 312b. The second inner surface 313 includes the second upper inner surface 313a and the fourth side inner surface 313b. Referring to FIG. 9, the first upper inner surface 312a is located on the surface close to a side of the first light-emitting sub-element 2011 facing away from the driving substrate 600. That is, the first upper inner surface 312a is on a positive light emission side of the first light-emitting sub-element 2011 and is configured to converge and adjust the light emitted from the positive light emission side of the first light-emitting sub-element 2011. The third side inner surface 312b is connected to the first upper inner surface 312a. Therefore, the third side inner surface is on a side light emission surface of the first light-emitting sub-element 2011 and is configured to converge and adjust the light emitted from the side light emission side of the first light-emitting sub-element 2011. Similarly, referring to FIG. 9, the second upper inner surface 313a is located on the surface of the second light-emitting sub-element 2012 facing away from the driving substrate 600. That is, the second upper inner surface 313a is on a positive light emission side of the second light-emitting sub-element 2012 and is configured to converge and adjust the light emitted from the positive light emission side of the second light-emitting sub-element 2012. The fourth side inner surface 313b is connected to the second upper inner surface 313a. Therefore, the fourth side inner surface 313b is on a side light emission surface of the second light-emitting sub-element 2012 and is configured to converge and adjust the light emitted from the side light emission side of the second light-emitting sub-element 2012.

Further, the first light-emitting sub-element 2011 is located on a side of the second light-emitting sub-element 2012 facing the edge of the light-emitting panel 10. Therefore, the first light-emitting sub-element 2011 is more likely to generate light leakage at the gap at the edge of the light-emitting panel 10 than the second light-emitting sub-element 2012. That is to say, the light emission effect of the first light-emitting sub-element 2011 is worse than the light emission effect of the second light-emitting sub-element 2012. Therefore, it is necessary to adjust the light emission effect of the first light-emitting sub-element 2011 to a greater extent by virtue of the first light emission adjustment structure 310, thereby ensuring a better convergence effect on the light emitted from the first light-emitting sub-element 2011 after adjustment.

In an embodiment, the distribution density of Fresnel rings in the first Fresnel lens on the first upper inner surface 312a is adjusted to be greater than or equal to the distribution density of Fresnel rings in the first Fresnel lens on the second upper inner surface 313a. In combination with the convergence effect on the transmitted light by the Fresnel lens, such an arrangement may ensure the light emission adjustment effect of the first light emission adjustment structure 310 on the first light-emitting sub-element 2011 and the second light-emitting sub-element 2012 separately and further ensure a better light emission modulation effect of the first light emission adjustment structure 310 on the first light-emitting sub-element 2011, thereby improving the light emission effect of the first light-emitting sub-element 2011 and reducing or avoiding light leakage at the gap at the edge of the light-emitting panel 10. Further, the distribution density of Fresnel rings in the second Fresnel lens on the third side inner surface 312b may also be adjusted to be greater than or equal to the distribution density of Fresnel rings in the second Fresnel lens on the fourth side inner surface 313b. Such an arrangement may also improve the light emission effect of the first light-emitting sub-element 2011 and reduce or avoid light leakage at the gap at the edge of the light-emitting panel 10. Moreover, the distribution density of Fresnel rings in the first Fresnel lens on the first upper inner surface 312a may be adjusted to be greater than or equal to the distribution density of Fresnel rings in the first Fresnel lens on the second upper inner surface 313a, and the distribution density of Fresnel rings in the second Fresnel lens on the third side inner surface 312b may be adjusted to be greater than or equal to the distribution density of Fresnel rings in the second Fresnel lens on the fourth side inner surface 313b, thereby sufficiently improving the light emission effect of the first light-emitting sub-element 2011 and reducing or avoiding light leakage at the gap at the edge of the light-emitting panel 10.

FIG. 10 is an enlarged view of a first light emission adjustment structure of the fifth type according to an embodiment of the present application. Referring to FIG. 10, the plurality of first light-emitting elements 201 include a first light-emitting sub-element 2011 and a second light-emitting sub-element 2012. The first light-emitting sub-element 2011 is located on a side of the second light-emitting sub-element 2012 facing the edge of the light-emitting panel 10. The first light-emitting sub-element 2011 includes a first upper light-emitting surface 2011a and a third side light-emitting surface 2011b. The second light-emitting sub-element 2012 includes a second upper light-emitting surface 2012a and a fourth side light-emitting surface 2012b. The first light emission adjustment structure 310 includes a first inner surface 312 and a second inner surface 313, where the first inner surface 312 at least partially covers the first light-emitting sub-element 2011, and the second inner surface 313 at least partially covers the second light-emitting sub-element 2012. The first inner surface 312 includes a first upper inner surface 312a and a third side inner surface 312b. The second inner surface 313 includes a second upper inner surface 313a and a fourth side inner surface 313b. The minimum distance between the first upper inner surface 312a and the first upper light-emitting surface 2011a is less than or equal to the minimum distance between the second upper inner surface 313a and the second upper light-emitting surface 2012a. Moreover/alternatively, the minimum distance between the third side inner surface 312b and the third side light-emitting surface 2011b is less than or equal to the minimum distance between the fourth side inner surface 313b and the fourth side light-emitting surface 2012b.

The less the distance between the inner surface of the first light emission adjustment structure 310 facing the first light-emitting element 201 and the first light-emitting element 201 is, the more obvious the light concentration adjustment effect on the light emitted from the first light-emitting element 201 by the first light emission adjustment structure 310 is. In an embodiment, the minimum distance between the first upper inner surface 312a and the first upper light-emitting surface 2011a is less than or equal to the minimum distance between the second upper inner surface 313a and the second upper light-emitting surface 2012a. In combination with the convergence effect on the transmitted light by the Fresnel lens, such an arrangement may ensure the light emission adjustment effect of the first light emission adjustment structure 310 on the first light-emitting sub-element 2011 and the second light-emitting sub-element 2012 separately and further ensure a better light emission modulation effect of the first light emission adjustment structure 310 on the first light-emitting sub-element 2011, thereby reducing or avoiding light leakage at the gap at the edge of the light-emitting panel 10. Further, the minimum distance between the third side inner surface 312b and the third side light-emitting surface 2011b may be less than or equal to the minimum distance between the fourth side inner surface 313b and the fourth side light-emitting surface 2012b, also ensuring a better light emission modulation effect of the first light emission adjustment structure 310 on the first light-emitting sub-element 2011 and reducing or avoiding light leakage at the gap at the edge of the light-emitting panel 10. Moreover, the minimum distance between the first upper inner surface 312a and the first upper light-emitting surface 2011a may be less than or equal to the minimum distance between the second upper inner surface 313a and the second upper light-emitting surface 2012a, and the minimum distance between the third side inner surface 312b and the third side light-emitting surface 2011b is adjusted to be less than or equal to the minimum distance between the fourth side inner surface 313b and the fourth side light-emitting surface 2012b, further ensuring a better light emission modulation effect of the first light emission adjustment structure 310 on the first light-emitting sub-element 2011 and reducing or avoiding light leakage at the gap at the edge of the light-emitting panel 10.

With continued reference to FIGS. 1 to 4, the light-emitting panel 10 further includes a plurality of second light-emitting elements 202 disposed in the second light-emitting region 102. The light-emitting panel 10 further includes a plurality of reflective units 203. A reflective unit 203 is disposed between at least two adjacent second light-emitting elements 202.

In an embodiment, referring to FIG. 2, the light-emitting elements 200 disposed in the light-emitting panel 10 further include the second light-emitting elements 202. The second light-emitting elements 202 are disposed in the second light-emitting region 102. The first light-emitting elements 201 are used for ensuring the light-emitting effect of the first light-emitting region 101. The second light-emitting elements 202 are used for ensuring the light-emitting effect of the second light-emitting region 102.

Further, referring to FIG. 2, the light-emitting panel 10 further includes a plurality of reflective units 203. A reflective unit 203 is disposed between two adjacent second light-emitting elements 202. In this case, when the light emitted from a second light-emitting element 202 is transmitted to the reflective unit 203, the light can be continuously emitted to the light emission side of the light-emitting panel 10 through reflection, thereby ensuring the light-emitting effect of the light-emitting panel 10. Further, the arrangement of the reflective unit 203 may also block light crosstalk between the two adjacent second light-emitting elements 202, helping provide the light emission contrast of the light-emitting panel 10.

On the basis of the preceding embodiments, as a feasible embodiment, referring to FIG. 3, in order to avoid crosstalk between two adjacent first light-emitting elements 201 and to ensure the light-emitting effect of the first light-emitting elements 201 in the first light-emitting region 101, a reflective unit 203 may also be disposed between the two adjacent first light-emitting elements 201.

Further, as another feasible embodiment, as shown in FIGS. 2 and 4, the first light emission adjustment structure 310 may effectively modulate the light emission of the first light-emitting elements 201. Therefore, in the light-emitting panel 10, no reflective unit 203 may be disposed between two adjacent first light-emitting elements 201. Moreover, the arrangement in which no reflective unit 203 is disposed between two adjacent first light-emitting elements 201 provides a more sufficient space for the arrangement of the first light-emitting elements 201 so that the number of first light-emitting elements 201 in the first light-emitting region 101 is increased.

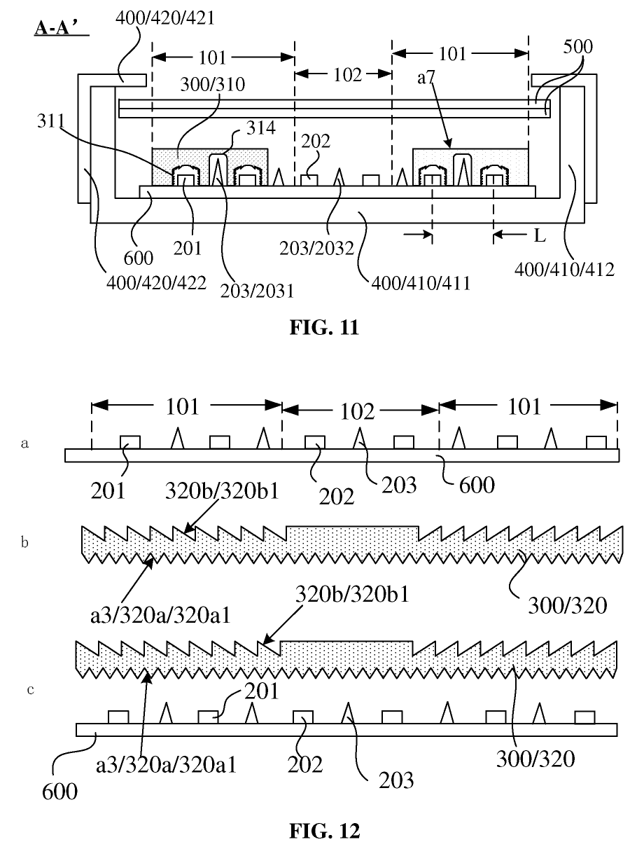

FIG. 11 is the fourth sectional view taken along line A-A' of FIG. 1. Referring to FIG. 11, the reflective units 203 include first reflective units 2031 and second reflective units 2032. A first reflective unit 2031 is disposed in the first light-emitting region 101 and located between two adjacent first light-emitting elements 201. A second reflective unit 2032 is disposed in the second light-emitting region 102 and located between two adjacent second light-emitting elements 202. The height of the first reflective unit 2031 is greater than the height of the second reflective unit 2032 in the light emission direction of the first light-emitting elements 201.

In an embodiment, the reflective units 203 include the first reflective units 2031 and the second reflective units 2032. A first reflective unit 2031 is located in the first light-emitting region 101 and between two adjacent first light-emitting elements 201. The laterally emitted light of the first light-emitting elements 201 is reflected by the first reflective unit 2031, thereby improving the brightness of the first light-emitting region 101. A second reflective unit 2032 is located in the second light-emitting region 102 and between two adjacent second light-emitting elements 202. The laterally emitted light of the second light-emitting elements 202 is reflected by the second reflective unit 2032, thereby improving the brightness of the second light-emitting region 102.

Further, the first light emission adjustment structure 310 is disposed in the first light-emitting region 101. Moreover, the first light emission adjustment structure 310 may adjust the light emission effect of the first light-emitting elements 201, thereby ensuring that the light emitted from the first light-emitting elements 201 has a better convergence effect than the light emitted from the second light-emitting elements 202. Therefore, the first reflective unit 2031 and the second reflective unit 2032 may be differentiated according to the light emission effects of different light-emitting elements 200. In an embodiment, the light emitted from a first light-emitting element 201 and through the first light emission adjustment structure 310 is more convergent. That is, the angle between the light emitted from the first light-emitting element 201 and through the first light emission adjustment structure 310 and the thickness direction of the light-emitting panel is smaller. Therefore, in order to ensure that the first reflective unit 2031 can receive the lateral light emitted from the first light-emitting element 201 and through the first light emission adjustment structure 310, the height of the first reflective unit 2031 may be adjusted to be greater than the height of the second reflective unit 2032 in the light emission direction of the first light-emitting element 201, thereby ensuring that the first reflective unit 2031 can adjust the lateral light emitted from the first light-emitting element 201 and through the first light emission adjusting structure 310. The second reflective unit 2032 can adjust the lateral light emitted from the second light-emitting element 202, thus better ensuring the light emission effect of the light-emitting panel 10.

With continued reference to FIG. 11, the reflective units 203 include first reflective units 2031 and second reflective units 2032. A first reflective unit 2031 is disposed in the first light-emitting region 101 and located between two adjacent first light-emitting elements 201. The second reflective unit 2032 is disposed in the second light-emitting region 102 and located between two adjacent second light-emitting elements 202. The first light emission adjustment structure 310 further includes a plurality of second avoidance recesses 314. A second avoidance recess 314 covers a first reflective unit 2031.

Further, referring to FIG. 11, the reflective units 203 include the first reflective units 2031 and the second reflective units 2032. Both the first reflective units 2031 and the first light-emitting elements 201 are located in the first light-emitting region 101. Moreover, the first light emission adjustment structure 310 is further disposed in the first light-emitting region 101 of the light-emitting panel 10. The first light emission adjustment structure 310 includes a plurality of first avoidance recesses 311 for covering the first light-emitting elements 201. The first light emission adjustment structure 310 further includes a plurality of second avoidance recesses 314 for covering the first reflective units 2031.

In an embodiment, the arranged first avoidance recesses 311 and the arranged second avoidance recesses 314 may perform structure protection on the first light-emitting elements 201 and the first reflective units 203, respectively. In another aspect, the first light emission adjustment structure 310 may be transferred to the light-emitting panel 10 after the preparation of the first avoidance recesses 311 and the second avoidance recesses 314. Therefore, the arrangement of the first avoidance recesses 311 and the second avoidance recesses 314 can ensure the transfer accuracy of the first light emission adjustment structure 310 and ensure the structural stability and reliability of the light-emitting panel 10.

With continued reference to FIG. 11, in the light emission direction of the first light-emitting elements 201, the height of a first reflective unit 2031 is greater than the height of a first light-emitting element 201, and the maximum recess depth of a second avoidance recess 314 is greater than the maximum recess depth of a first avoidance recess 311.

Further, referring to FIG. 11, in the first light emission adjustment structure 310, the light emitted by the first light-emitting element 201 is adjusted to ensure that the light emitted from the first light-emitting element 201 and through the first light emission adjustment structure 310 is more convergent. That is, the angle between the light emitted from the first light-emitting element 201 and through the first light emission adjustment structure 310 and the thickness direction of the light-emitting panel is smaller. Therefore, in order to ensure that the first reflective unit 2031 can receive the lateral light emitted from the first light-emitting element 201 and through the first light emission adjustment structure 310, the height of the first reflective unit 2031 may be adjusted to be greater than the height of the first light-emitting element 201, thereby ensuring that the first reflective unit 2031 can reflect the light emitted from the first light-emitting element 201 and ensuring the brightness of the first light-emitting region 101.

Further, referring to FIG. 11, the height of the first reflective unit 2031 is greater than the height of the first light-emitting element 201. Therefore, in the first light emission adjustment structure 310, the maximum recess depth of the second avoidance recess 314 is greater than the maximum recess depth of the first avoidance recess 311. In this case, it may ensure that the first avoidance recess 311 may completely accommodate the first light-emitting element 201 and that the second avoidance recess 314 may completely accommodate the first reflective unit 2031.

With continued reference to FIGS. 2 and 5 to 11, a surface of the first light emission adjustment structure 310 facing away from the first light-emitting elements 310 includes a plane.

Further, referring to FIGS. 2 and 5 to 11 and specifically referring to a region indicated by arrow a7 in FIG. 11, the surface of the first light emission adjustment structure 310 facing away from the first light-emitting elements 310 includes the plane. Such an arrangement may ensure the structural flatness of the first light emission adjustment structure 310, helping provide another layer structure or the like on a side of the first light emission adjustment structure 310 facing away from the light-emitting elements 200.

With continued reference to FIGS. 2 and 11, the distance L between two adjacent first light-emitting elements 201 satisfies that L ≤ 6 mm.

Exemplarily, in the first light-emitting region 101, the distance L between two adjacent first light-emitting elements 201 satisfies that L ≤ 6 mm. L may be any value of 1 mm, 2 mm, 4 mm, 5.5 mm, or 6 mm. The specific value of L is not limited in the present application. Therefore, when the distance between two adjacent first light-emitting elements 201 is less than or equal to 6 mm in the region where the first light emission adjustment structure 310 is provided, the adjustment effect of a Fresnel lens disposed in the first light emission adjustment structure 310 is more obvious, better ensuring the light emission effect of the light-emitting panel 10.

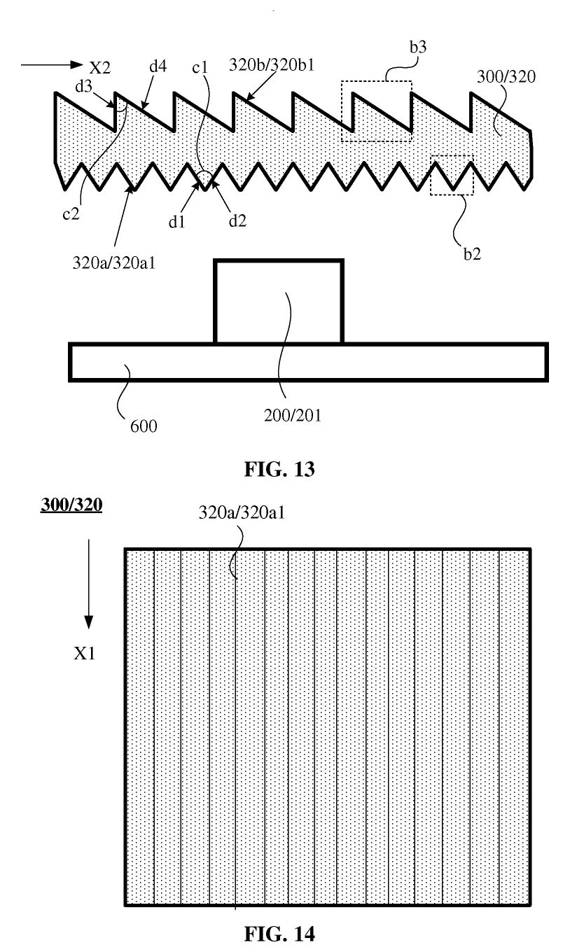

FIG. 12 is a view of the preparation process of another light-emitting panel according to an embodiment of the present application. FIG. 13 is an enlarged view of a second light emission adjustment structure of the first type according to an embodiment of the present application. Referring to FIGS. 3, 4, 12, and 13, the light emission adjustment structure 300 includes a second light emission adjustment structure 320. The second light emission adjustment structure 320 includes a light entry adjustment surface 320a and a light emission adjustment surface 320b, where the light entry adjustment surface 320a faces the first light-emitting elements 201, and the light emission adjustment surface 320b faces away from the first light-emitting elements 201. The light entry adjustment surface 320a includes a first light entry adjustment surface portion 320a1. The light emission adjustment surface 320b includes a first light emission adjustment surface portion 320b1. In the light emission direction of the first light-emitting elements 201, the first light entry adjustment surface portion 320a1 covers at least one first light-emitting element 201. The first light emission adjustment surface portion 320b1 at least partially overlaps the first light entry adjustment surface portion 320a1. The first light entry adjustment surface portion 320a1 is provided with a plurality of inversing prisms. The first light emission adjustment surface portion 320b1 is provided with a plurality of right-angle prisms.

Referring to FIGS. 3 and 4, the light emission adjustment structure 300 includes the second light emission adjustment structure 320. The second light emission adjustment structure 320 includes the light entry adjustment surface 320a and the light emission adjustment surface 320b. The light entry adjustment surface 320a is located on a side of the second light emission adjustment structure 320 facing the first light-emitting elements 201. The light emission adjustment surface 320b is located on a side of the second light emission adjustment structure 320 facing away from the first light-emitting elements 201. Through the light entry adjustment surface 320a and the light emission adjustment surface 320b, the second light emission adjustment structure 320 may adjust the light emitted from the first light-emitting elements 201, thus improving the brightness of the first light-emitting region 101.

In an embodiment, the light entry adjustment surface 320a includes the first light entry adjustment surface portion 320a1. In the light emission direction of the first light-emitting elements 201, the first light entry adjustment surface portion 320a1 covers at least one first light-emitting element 201. Therefore, the first light entry adjustment surface portion 320a1 may adjust the light emitted from the first light-emitting elements 201. In an embodiment, the first light entry adjustment surface portion 320a1 is provided with a plurality of inversing prisms (reference may be made to a region indicated by b2 in FIG. 13). The light emitted from the first light-emitting elements 201 may be diffused by the arranged inversing prisms. Further, the light emission adjustment surface 320b includes the first light emission adjustment surface portion 320b1. In the light emission direction of the first light-emitting elements 201, the first light emission adjustment surface portion 320b1 at least partially overlaps the first light entry adjustment surface portion 320a1. Therefore, the first light emission adjustment surface portion 320b1 may perform further modulation on the light adjusted by the first light entry adjustment surface portion 320a1. In an embodiment, the first light emission adjustment surface portion 320b1 is provided with a plurality of right-angle prisms (reference may be made to a region indicated by b3 in FIG. 13). The light diffused by the inversing prisms is adjusted through the arranged right-angle prisms, ensuring that the light is emitted to the edge region of the light-emitting region of the light-emitting panel 10, improving the brightness of the edge region of the light-emitting panel 10, alleviating the problem of low brightness caused by insufficient mutual compensation between light-emitting elements 200 in the edge region of the light-emitting panel 10, and ensuring the overall light-emitting effect of the light-emitting panel 10.

In the embodiments of the present disclosure, referring to FIG. 12, the preparation process of the light-emitting panel 10 including the second light emission adjustment structure 320 is as follows: First, referring to step a in FIG. 12, a first light-emitting element 201 or the like is prepared in the first light-emitting region 101; then referring to step b in FIG. 12, the second light emission adjustment structure 320 is provided, and the second light emission adjustment structure 320 includes the light entry adjustment surface 320a and the light emission adjustment surface 320b, with the light entry adjustment surface 320a provided with the inversing prisms and the light emission adjustment surface 320b provided with the right-angle prisms; finally, referring to step c in FIG. 12, the second light emission adjustment structure 320 is placed on the light emission side of the first light-emitting elements 201, and the light is diffused by the inversing prisms and is adjusted to the edge through the right-angle prisms, thereby improving the light emission amount at the edge of the light-emitting panel 10. In this regard, it may be understood that the second light emission adjustment structure 320 is a structure prepared by another process first and then placed on a side of the first light-emitting elements 201. Therefore, when the surface of the second light emission adjustment structure 330 is designed with the inversing prisms and the right-angle prisms, the related preparation process does not cause damage to the light-emitting elements 200 and thus does not affect the structural stability of the light-emitting panel 10.

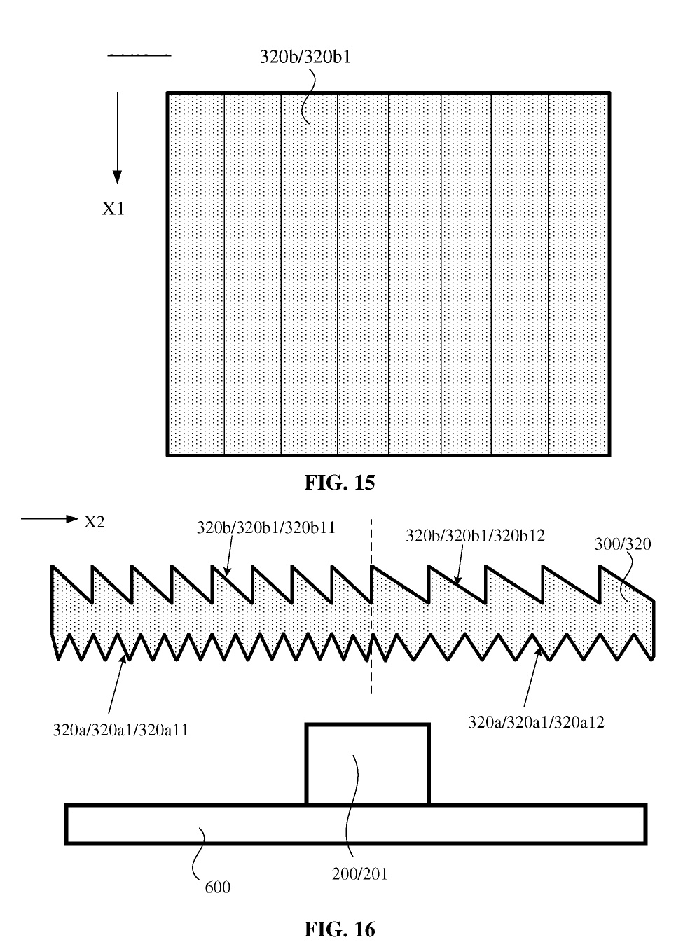

FIG. 14 is a top view of a first light entry adjustment surface portion in the second light emission adjustment structure of FIG. 13. FIG. 15 is a top view of a first light emission adjustment surface portion in the second light emission adjustment structure of FIG. 13. With continued reference to FIGS. 13 to 15, the inversing prisms extend in a first direction X1 and are arranged in a second direction X2. The right-angle prisms extend in the first direction X1 and are arranged in the second direction X2. The first direction X1 intersects with the second direction X2. Both the first direction X1 and the second direction X2 intersect with the light emission direction of the first light-emitting elements 201.

In an embodiment, the first light entry adjustment surface portion 320a1 includes a plurality of inversing prisms. The plurality of inversing prisms extend in a first direction X1 and are arranged in a second direction X2. Referring to FIGS. 13 and 14, the inversing prisms may be understood as a plurality of prism structures arranged in an array in one dimension, thus ensuring that the light adjusted by the inversing prisms is consistent in light emission in the first direction X1. In an embodiment, the first light emission adjustment surface portion 320b1 includes a plurality of right-angle prisms. The plurality of right-angle prisms extend in the first direction X1 and are arranged in the second direction X2. Referring to FIGS. 13 and 15, the right-angle prisms may be understood as a plurality of prism structures arranged in an array in one dimension, thus ensuring that the light adjusted by the right-angle prisms is consistent in light emission in the first direction X1.

In general, the light adjusted by the inversing prisms and the right-angle prisms is consistent in light emission in the first direction X1, thus ensuring that the light emission effect of the first light-emitting region 101 is improved and ensuring the brightness of the first light-emitting region 101.

With continued reference to FIG. 13, the sectional shape of an inversing prism is an isosceles triangle. The angle between a first leg d1 in the isosceles triangle and a second leg d2 in the isosceles triangle is a first vertex angle c1. The first vertex angle c1 faces a side of a first light-emitting element 201. The first vertex angle is in the range of 80° to 100°. The sectional shape of a right-angle prism is a right triangle. The angle between a first right-angle side d3 in the right triangle and a hypotenuse d4 in the right triangle is a second vertex angle c2. The second vertex angle c2 faces away from a side of a first light-emitting element 201. The second vertex angle is in the range of 60° to 75°.

In an embodiment, referring to FIG. 13, the sectional shape of the inversing prism disposed on the first light entry adjustment surface portion 320a1 may be an isosceles triangle. The isosceles triangle includes the first vertex angle c1. The first vertex angle c1 is the included angle between the first leg d1 in the isosceles triangle and the second leg d2 in the isosceles triangle. In an embodiment, the angle range of the first vertex angle c1 may be set to between 80° and 100°. For example, the first vertex angle c1 may be any value among 80°, 90°, 95°, or 100°. The present application does not limit the specific value of the first vertex angle c1, which may be adaptively adjusted according to actual needs. The arrangement in which the sectional shape of the inversing prism is an isosceles triangle may ensure that the inversing prism performs an even light adjustment on surrounding first light-emitting elements 201 so that the light generated by the first light-emitting elements 201 can be effectively diffused into the second light emission adjustment structure 320.

Further, referring to FIG. 13, the sectional shape of the right-angle prism disposed on the first light emission adjustment surface portion 320b1 is a right triangle. The right triangle includes the second vertex angle c2. The second vertex angle c2 is the angle between the first right-angle side d3 in the right triangle and the hypotenuse d4 in the right triangle. In an embodiment, the angle range of the second vertex angle c2 may be set to between 60° and 75°. For example, the second vertex angle c2 may be any value among 60°, 70°, or 75°. The present application does not limit the specific value of the first vertex angle c1, which may be adaptively adjusted according to actual needs. The arrangement in which the sectional shape of the right-angle prism is a right triangle enables the light transmitted to the second light emission adjustment structure 320 to be effectively adjusted to the edge region of the light-emitting region, improves the brightness at the edge of the light-emitting panel 10, and ensures the overall light emission effect of the light-emitting panel 10.

FIG. 16 is an enlarged view of a second light emission adjustment structure of the second type according to an embodiment of the present application. Referring to FIG. 16, the first light entry adjustment surface portion 320a1 includes a first light entry adjustment region 320a11 and a second light entry adjustment region 320a12. The first light entry adjustment region 320a11 is located on a side of the second light entry adjustment region 320a12 facing the edge of the light-emitting panel 10. The distribution density of inversing prisms in the first light entry adjustment region 320a11 is greater than or equal to the distribution density of inversing prisms in the second light entry adjustment region 320a12. Moreover/alternatively, the first light emission adjustment surface portion 320b1 includes a first light emission adjustment region 320b11 and a second light emission adjustment region 320b12. The first light emission adjustment region 320b11 is located on a side of the second light emission adjustment region 320b12 facing the edge of the light-emitting panel 10. The distribution density of right-angle prisms in the first light emission adjustment region 320b11 is greater than or equal to the distribution density of right-angle prisms in the second light emission adjustment region 320b12.

In order to better adjust the brightness at the edge of the light-emitting region of the light-emitting panel 10, the surface structure in the second light emission adjustment structure 320 for adjusting the light transmission path may be further adjusted. In an embodiment, the first light entry adjustment surface portion 320a1 and/or the first light emission adjustment surface portion 320b1 is further adjusted, thereby further improving the brightness at the edge of the light-emitting region of the light-emitting panel 10 and improving the brightness of the edge region of the light-emitting panel 10.

In an embodiment, referring to FIG. 16, the first light entry adjustment surface portion 320a1 includes the first light entry adjustment region 320a11 and the second light entry adjustment region 320a12. The first light entry adjustment region 320a11 is located on a side of the second light entry adjustment region 320a12 facing the edge of the light-emitting panel 10. In order to ensure the effective adjustment of the light emitted from the first light-emitting elements 201 closer to the edge, the distribution density of right-angle prisms in the first light emission adjustment region 320b11 may be adjusted to be greater than or equal to the distribution density of right-angle prisms in the second light emission adjustment region 320b12. The distribution density of inversing prisms may be understood as the arrangement number of inversing prisms per unit area. The distribution density of right-angle prisms in the first light emission adjustment region 320b11 is adjusted to be equal to the distribution density of right-angle prisms in the second light emission adjustment region 320b12, thereby reducing the process preparation difficulty of the first light entry adjustment surface portion 320a1. The distribution density of right-angle prisms in the first light emission adjustment region 320b11 is adjusted to be greater than the distribution density of right-angle prisms in the second light emission adjustment region 320b12, thereby ensuring that the first light entry adjustment region 320a11 may better adjust the light emitted from the first light-emitting elements 201 to the inside of the second light emission adjustment structure 320.

In an embodiment, referring to FIG. 16, the first light emission adjustment surface portion 320b1 includes the first light emission adjustment region 320b11 and the second light emission adjustment region 320b12. The first light emission adjustment region 320b11 is located on a side of the second light emission adjustment region 320b12 facing the edge of the light-emitting panel 10. In order to ensure that the brightness at the edge of the light-emitting region of the light-emitting panel 10 is improved, the distribution density of right-angle prisms in the first light emission adjustment region 320b11 may be adjusted to be greater than or equal to the distribution density of right-angle prisms in the second light emission adjustment region 320b12. The distribution density of right-angle prisms may be understood as the arrangement number of right-angle prisms per unit area. The distribution density of right-angle prisms in the first light emission adjustment region 320b11 is adjusted to be equal to the distribution density of right-angle prisms in the second light emission adjustment region 320b12, thereby reducing the process preparation difficulty of the first light emission adjustment surface portion 320b1. The distribution density of right-angle prisms in the first light emission adjustment region 320b11 is adjusted to be greater than the distribution density of right-angle prisms in the second light emission adjustment region 320b12, thereby ensuring that more light may be emitted from the first light emission adjustment region 320b11 and improving the brightness of the edge region of the light-emitting panel 10.

Further, referring to FIG. 16, the distribution density of inversing prisms in the first light entry adjustment region 320a11 may be adjusted to be greater than or equal to the distribution density of inversing prisms in the second light entry adjustment region 320a12; moreover, the distribution density of right-angle prisms in the first light emission adjustment region 320b11 may be adjusted to be greater than or equal to the distribution density of right-angle prisms in the second light emission adjustment region 320b12. Therefore, such an arrangement may also represent diversified arrangement manners of the second light emission adjustment structure 320, which may be adaptively adjusted according to actual needs.

With continued reference to FIGS. 3 and 4, the light-emitting panel 10 further includes a plurality of second light-emitting elements 202 disposed in the second light-emitting region 102. The light entry adjustment surface 320a includes a second light entry adjustment surface portion 320a2. The light emission adjustment surface 320b includes a second light emission adjustment surface portion 320b2. In the light emission direction of the second light-emitting elements 202, the second light entry adjustment surface portion 320a2 covers at least one second light-emitting element 202. The second light emission adjustment surface portion 320b2 at least partially overlaps the second light entry adjustment surface portion 320a2. The second light entry adjustment surface portion 320a2 is provided with a plurality of inversing prisms. The second light emission adjustment surface portion 320b2 includes a plane.

In an embodiment, referring to FIGS. 3 and 4, the light-emitting elements 200 disposed in the light-emitting panel 10 further include the second light-emitting elements 202. The second light-emitting elements 202 are disposed in the second light-emitting region 102. The first light-emitting elements 201 are used for ensuring the light-emitting effect of the first light-emitting region 101. The second light-emitting elements 202 are used for ensuring the light-emitting effect of the second light-emitting region 102.

In the second light emission adjustment structure 320, the light entry adjustment surface 320a includes the second light entry adjustment surface portion 320a2. In the light emission direction of the second light-emitting elements 202, the second light entry adjustment surface portion 320a2 covers at least one second light-emitting element 202. Moreover, the second light entry adjustment surface portion 320a2 is provided with a plurality of inversing prisms. Therefore, the light emitted from the second light-emitting elements 202 may also be modulated through the second light emission adjustment structure 320. The light emitted from the second light-emitting elements 202 may be diffused through the plurality of inversing prisms, and in combination with the second light emission adjustment surface portion 320b2, the brightness of the first light-emitting region 101 and the brightness of the second light-emitting region 102 can be equalized.

Further, in the second light emission adjustment structure 320, the light emission adjustment surface 320b further includes the second light emission adjustment surface portion 320b2. In the light emission direction of the second light-emitting elements 202, the second light emission adjustment surface portion 320b2 at least partially overlaps the second light entry adjustment surface portion 320a2. Moreover, the second light emission adjustment surface portion 320b2 includes a plane. In this case, it may ensure that the light emitted from the second light emission adjustment structure 320 in the second light-emitting region 102 does not need to be emitted to the edge region of the light-emitting panel 10, thus ensuring the brightness of the second light-emitting region 102.

In an embodiment, referring to FIGS. 3 and 4, the distribution density of inversing prisms in the first light entry adjustment surface portion 320a1 is greater than or equal to the distribution density of inversing prisms in the second light entry adjustment surface portion 320a2.

Further, referring to FIGS. 3 and 4, the first light entry adjustment surface portion 320a1 located in the first light-emitting region 101 and the second light entry adjustment surface portion 320a2 located in the second light-emitting region 102 may be arranged differently. In an embodiment, the distribution density of inversing prisms in the first light entry adjustment surface portion 320a1 is adjusted to be greater than or equal to the distribution density of inversing prisms in the second light entry adjustment surface portion 320a2.

In an embodiment, referring to FIG. 4, the distribution density of inversing prisms in the first light entry adjustment surface portion 320a1 is adjusted to be equal to the distribution density of inversing prisms in the second light entry adjustment surface portion 320a2. Such an arrangement may reduce the design difficulty of the light entry adjustment surface 320a in the second light emission adjustment structure 320 and ensure that the overall structure of the second light emission adjustment structure 320 is more regular.

In an embodiment, referring to FIG. 3, the distribution density of inversing prisms in the first light entry adjustment surface portion 320a1 may be adjusted to be greater than the distribution density of inversing prisms in the second light entry adjustment surface portion 320a2. Such an arrangement may ensure a better light convergence effect on light by the second light emission adjustment structure 320 in the first light-emitting region 101 and ensure a better light convergence effect at the edge region of the light-emitting panel 10.

With continued reference to FIG. 3, the distance L between two adjacent first light-emitting elements 201 satisfies that L > 6 mm.

Exemplarily, in the first light-emitting region 101, the distance L between two adjacent first light-emitting elements 201 satisfies that L > 6 mm. L may be any value of 7mm, 8mm, 9mm, 9.5mm, or 10mm. The specific value of L is not limited in the present application. Therefore, when the distance between two adjacent first light-emitting elements 201 is greater than 6 mm in the region where the first light emission adjustment structure 310 is provided, the inversing prisms and the right-angle prisms are disposed on two sides of the second light emission adjustment structure 320, thereby better ensuring the light emission effect of the light-emitting panel 10.

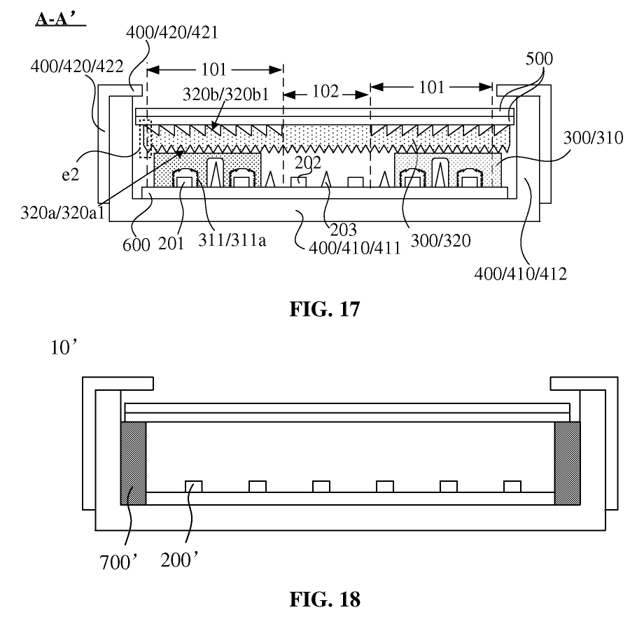

FIG. 17 is the fifth sectional view taken along line A-A' of FIG. 1. Referring to FIGS. 4 and 17, the light emission adjustment structure 300 includes a first light emission adjustment structure 310 and a second light emission adjustment structure 320. The first light emission adjustment structure 310 includes a plurality of first avoidance recesses 311. A first avoidance recess 311 covers at least one first light-emitting element 201. The first avoidance recess 311 includes an inner surface 311a. At least part of the inner surface 311a is provided with a Fresnel lens. The second light emission adjustment structure 320 is located on a side of the first light emission adjustment structure 310 facing away from the first light-emitting elements 201. The second light emission adjustment structure 320 includes a light entry adjustment surface 320a and a light emission adjustment surface 320b, where the light entry adjustment surface 320a is on a side of the second light emission adjustment structure 320 facing the first light-emitting elements 201, and the light emission adjustment surface 320b is on a side of the second light emission adjustment structure 320 facing away from the first light-emitting elements 201. The light entry adjustment surface 320a includes a first light entry adjustment surface portion 320a1. The light emission adjustment surface 320b includes a first light emission adjustment surface portion 320b1. In the light emission direction of the first light-emitting elements 201, the first light entry adjustment surface portion 320a1 covers at least one first light-emitting element 201. The first light emission adjustment surface portion 320b1 at least partially overlaps the first light entry adjustment surface portion 320a1. The first light entry adjustment surface portion 320a1 is provided with a plurality of inversing prisms. The first light emission adjustment surface portion 320b1 is provided with a plurality of right-angle prisms.

In an embodiment, referring to FIGS. 4 and 17, the light-emitting panel 10 includes the first light emission adjustment structure 310 and the second light emission adjustment structure 320. The light emitted from the first light-emitting elements 201 can be effectively modulated through the first light emission adjustment structure 310 and the second light emission adjustment structure 320, ensure the light-emitting effect of the first light-emitting region 101, and ensure the overall light-emitting effect of the light-emitting panel 10.

Further, referring to FIGS. 4 and 17, in the first light emission adjustment structure 310, the first avoidance recess 311 covers the first light-emitting element 201. The surface of the first avoidance recess 311 facing the first light-emitting element 201 is used for adjusting the light emitted from the first light-emitting element 201 so that the surface of the first avoidance recess 311 facing the first light-emitting element 201 can be non-planar, thus ensuring that the light-emitting intensity of the first light-emitting region 101 is increased. In an embodiment, in order to ensure the adjustment of the light emitted from the first light-emitting element 201, the inner surface 311a of the first avoidance recess 311 is designed to be non-planar. Exemplarily, referring to FIGS. 4 and 17, at least part of the inner surface 311a is provided with the Fresnel lens.

Further, referring to FIGS. 4 and 17, the second light emission adjustment structure 320 includes the light entry adjustment surface 320a and the light emission adjustment surface 320b. The light entry adjustment surface 320a is located on a side of the second light emission adjustment structure 320 facing the first light-emitting elements 201. The light emission adjustment surface 320b is located on a side of the second light emission adjustment structure 320 facing away from the first light-emitting elements 201. Through the light entry adjustment surface 320a and the light emission adjustment surface 320b, the second light emission adjustment structure 320 may adjust the light emitted from the first light-emitting elements 201, thus improving the brightness of the first light-emitting region 101. In an embodiment, the light entry adjustment surface 320a includes the first light entry adjustment surface portion 320a1. In the light emission direction of the first light-emitting elements 201, the first light entry adjustment surface portion 320a1 covers at least one first light-emitting element 201. Therefore, the first light entry adjustment surface portion 320a1 may adjust the light emitted from the first light-emitting elements 201. In an embodiment, the first light entry adjustment surface portion 320a1 is provided with a plurality of inversing prisms The light emitted from the first light-emitting elements 201 may be diffused by the arranged inversing prisms. Further, the light emission adjustment surface 320b includes the first light emission adjustment surface portion 320b1. In the light emission direction of the first light-emitting elements 201, the first light emission adjustment surface portion 320b1 at least partially overlaps the first light entry adjustment surface portion 320a1. Therefore, the first light emission adjustment surface portion 320b1 may perform further modulation on the light adjusted by the first light entry adjustment surface portion 320a1. In an embodiment, the first light emission adjustment surface portion 320b1 is provided with a plurality of right-angle prisms. The light diffused by the inversing prisms is adjusted through the arranged right-angle prisms, ensuring that the light is emitted to the edge region of the light-emitting region of the light-emitting panel 10, improving the brightness of the edge region of the light-emitting panel 10, alleviating the problem of low brightness caused by insufficient mutual compensation between light-emitting elements 200 in the edge region of the light-emitting panel 10, and ensuring the overall light-emitting effect of the light-emitting panel 10.

In general, in the light-emitting panel 10 according to this embodiment of the present application, both the first light emission adjustment structure 310 and the second light emission adjustment structure 320 may be provided, effectively modulating the light emitted by the first light-emitting elements 201, improving the light-emitting efficiency of the first light-emitting region 101, and ensuring the light-emitting effect of the first light-emitting region 101.

With continued reference to FIGS. 4 and 17, in the light emission direction of the first light-emitting elements 201, the first light entry adjustment surface portion 320a1 covers the first light emission adjustment structure 310, and the first light emission adjustment surface portion 320b1 covers the first light emission adjustment structure 310.

In an embodiment, referring to FIGS. 4 and 17, in the light emission direction of the first light-emitting elements 201, the first light entry adjustment surface portion 320a1 in the second light emission adjustment structure 320 covers the first light emission adjustment structure 310, and the first light emission adjustment surface portion 320b1 in the second light emission adjustment structure 320 covers the first light emission adjustment structure 310. Therefore, the first light emission adjustment structure 310 covers each surface for light modulation in the second light emission adjustment structure 320, thereby ensuring that the light emitted from the first light-emitting elements 201 may be effectively modulated by the first light emission adjustment structure 310 and the second light emission adjustment structure 320, ensuring the adjustment effect of light efficiency, ensuring the light-emitting effect of the first light-emitting region 101, and ensuring the overall light emission effect of the light-emitting panel 10.

With continued reference to FIGS. 4 and 17, the first light emission adjustment structure 310 is in contact with the second light emission adjustment structure 320. An end portion of the first light entry adjustment surface portion 320a1 facing the edge of the light-emitting panel 10 is suspended.

In an embodiment, referring to FIGS. 4 and 17, the first light emission adjustment structure 310 is in contact with the second light emission adjustment structure 320. That is, the second light emission adjustment structure 320 is mounted and placed on a side of the first light emission adjustment structure 310 facing away from the light-emitting elements 200. The first light emission adjustment structure 310 and the second light emission adjustment structure 320 can support the overall light-emitting panel 10. Therefore, referring to region e1 in FIG. 4 and region e2 in FIG. 17, the end portion of the first light entry adjustment surface portion 320a1 facing the edge of the light-emitting panel 10 may be suspended.

Exemplarily, FIG. 18 is a structural view of a light emission panel in the related art. The light emission panel 10’ in the related art includes a plurality of light-emitting elements 200'. To ensure the overall structural stability of the light emission panel 10', a rubber frame structure 700' is designed in the edge region of the light emission panel 10'. Comparing FIG. 18 with FIGS. 2, 3, and 4, when the light-emitting panel 10 provided in embodiments of the present application includes the first light emission adjustment structure 310 and/or the second light emission adjustment structure 320, the rubber frame structure 700' in the related art does not need to be disposed at the edge of the light-emitting panel 10 close to the light emission adjustment structure 300 with the support function played. Therefore, the light-emitting panel 10 provided in embodiments of the present application may save the space of the edge region, enabling more light-emitting elements 200 to be arranged and implementing the narrow-bezel design of the light-emitting panel 10.

With continued reference to FIGS. 1 to 4, the light-emitting panel 10 further includes a plurality of second light-emitting elements 202 disposed in the second light-emitting region 102. The light-emitting panel 10 further includes a driving substrate 600. The driving substrate 600 is electrically connected to the first light-emitting elements 201 and the second light-emitting elements 202 for supplying drive signals to the first light-emitting elements 201 and the second light-emitting elements 202. Drive signals of at least part of the first light-emitting elements 201 are greater than drive signals of at least part of the second light-emitting elements 202.

In an embodiment, referring to FIGS. 1 to 4, the light-emitting panel 10 includes the first light-emitting region 101 and the second light-emitting region 102. A light-emitting element 200 located in the first light-emitting region 101 of the light-emitting panel 10 is a first light-emitting element 201. A light-emitting element 200 located in the second light-emitting region 102 of the light-emitting panel 10 is a second light-emitting element 202.

Since the first light-emitting element 201 is closer to the edge region of the light-emitting panel 10, the number of light-emitting elements 200 disposed on a side of the first light-emitting element 201 facing the edge of the light-emitting panel 10 is small, or no additional light-emitting element 200 is provided. Therefore, the number of light-emitting elements 200 that may perform mutual brightness compensation around the first light-emitting element 201 is relatively small, so that the brightness of the first light-emitting region 101 is weaker than the brightness of the second light-emitting region 102. Moreover, the arrangement position of the first light-emitting element 201 is closer to the edge region of the light-emitting panel 10, so that part of the light emitted from the first light-emitting element 201 is emitted in the gap at the edge of the light-emitting panel 10 where the first light-emitting element 201 faces. The gap at the edge may be understood as a boundary between a light-emitting region of the light-emitting panel 10 and a light non-emitting region of the light-emitting panel 10. The edge gap of the light-emitting panel 10 does not belong to an effective light-emitting region of the light-emitting panel 10, thus reducing the overall light emission efficiency of the first light-emitting element 201, making the brightness of the first light-emitting region 101 weaker than the brightness of the second light-emitting region 102, and causing light leakage in the edge region of the light-emitting panel 10. Further, in order to ensure that the brightness of the first light-emitting region 101 and the brightness of the second light-emitting region 102 are even or reduce the problem of low light-emitting efficiency caused by the arrangement position of the first light-emitting element 201, in the present application, drive signals of at least part of the first light-emitting elements 201 are set to be greater than drive signals of at least part of the second light-emitting elements 202 in the light-emitting panel 10. In this case, the brightness of the first light-emitting region 101 is improved by the arrangement difference of drive signals, ensuring an even light-emitting effect of the first light-emitting region 101 and the second light-emitting region 102 and ensuring the light-emitting effect of the light-emitting panel.

Further, in the related art, in order to improve the light emission efficiency of the first light-emitting elements 201 and make up for the light emission loss of the first light-emitting elements 201, drive signals supplied from the driving substrate 600 to the first light-emitting elements 201 are significantly stronger than drive signals supplied from the driving substrate 600 to the second light-emitting elements 201. In this embodiment of the present application, the arrangement of the light emission adjustment structure 310 may improve the brightness of the first light-emitting region 101 from the perspective of structures. Therefore, drive signals supplied from the driving substrate 600 to the first light-emitting elements 201 may be reduced as long as drive signals of at least part of the first light-emitting elements 201 are greater than drive signals of at least part of the second light-emitting elements 202, thus effectively reducing the power consumption of the driving substrate 600.

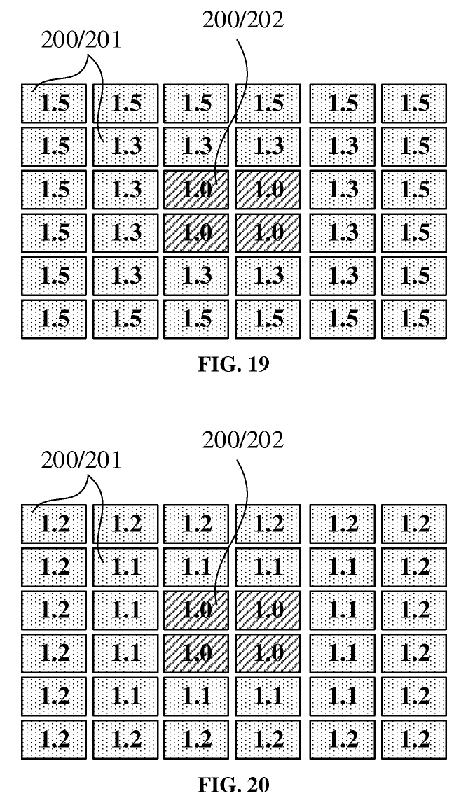

Exemplarily, FIG. 19 is a view of a drive signal supplied to a light-emitting element by a driving substrate in the related art. FIG. 20 is a view of a drive signal supplied to a light-emitting element by a driving substrate in the present application. Referring to FIGS. 19 and 20, FIGS. 19 and 20 illustrate a plurality of first light-emitting elements 201 and a plurality of second light-emitting elements 202. The specific number of light-emitting elements 200 in one light-emitting panel 10 may be adaptively adjusted. FIGS. 19 and 20 are used merely for exemplary description. A value shown on a light-emitting element 200 in FIGS. 19 and 20 may be understood as a magnitude relationship or a proportional relationship of the drive current supplied from the driving substrate 600 to the corresponding light-emitting element 200. Referring to FIG. 19, in the related art, the light-emitting effect of the first light-emitting region 101 may be ensured by supplying different driving currents to a first light-emitting element 201 and a second light-emitting element 202 by the driving substrate 600. Referring to FIGS. 19 and 20 for comparison, the light-emitting panel 10 provided in embodiments of the present application is provided with the light emission adjustment structure 300. The light emission adjustment structure 300 may modulate the light emission of the first light-emitting element 201 so that the driving substrate 600 may reduce a driving current to the first light-emitting element 201, which also ensures the light-emitting effect of the first light-emitting region 101. Therefore, the light-emitting panel 10 provided in embodiments of the present application has the advantage of low power consumption with the light emission effect ensured.

Referring to FIGS. 2 to 4, the light-emitting panel 10 further includes a color conversion layer 510 and a diffusion layer 520 that are disposed on a side of the light emission adjustment structure 300 facing away from the first light-emitting elements 201. The color conversion layer 510 is located between the diffusion layer 520 and the light emission adjustment structure 300; alternatively, the color conversion layer 510 is located on a side of the diffusion layer 520 facing away from the light emission adjustment structure 300.

Further, referring to FIGS. 2 to 4, the light-emitting panel 10 further includes the color conversion layer 510 and the diffusion layer 520. The diffusion layer 520 may implement the diffusion of light and improve the light emission uniformity of the light-emitting panel 10. The color conversion layer 510 includes color conversion ions (not specifically shown) such as quantum dots. The color adjustment of the light emitted from the light-emitting elements 200 may be implemented through the color conversion layer 510. Exemplarily, a light-emitting element 200 emits blue light, which may be converted into white light after passing through the color conversion layer 510.

The arrangement position of the color conversion layer 510 and the arrangement position of the diffusion layer 520 are flexible. Referring to FIGS. 2 and 3, the color conversion layer 510 is located on a side of the diffusion layer 520 facing away from the light emission adjustment structure 300; alternatively, referring to FIG. 4, the color conversion layer 510 is located on a side of the diffusion layer 520 facing the light emission adjustment structure 300.

In the embodiments of the present disclosure, the light-emitting panel 10 may further include a brightness enhancement film (not specifically shown). The brightness enhancement film may further brighten the light emitted from the light-emitting elements 200 and improve the light emission effect of the light-emitting panel 10. Layer structures provided on a side of the light emission adjustment structure 300 facing away from the light-emitting elements 200 may be adaptively adjusted according to actual needs, which is not specifically limited in the present application.

A light-emitting element includes a sub-micron light-emitting diode.

The light-emitting element may include the sub-micron light-emitting diode (mini-LED). Sub-micron light-emitting diodes are a type of semiconductor electronic components for converting electric energy into light energy. With the feature of small size, long service life, colorful colors and low energy consumption, sub-micron light-emitting diodes have been widely used. Due to the small size of electronic components such as sub-micron light-emitting diodes, more light-emitting elements can be arranged in the light-emitting panel of the same size, helping implement the refined light emission control of the light-emitting panel.

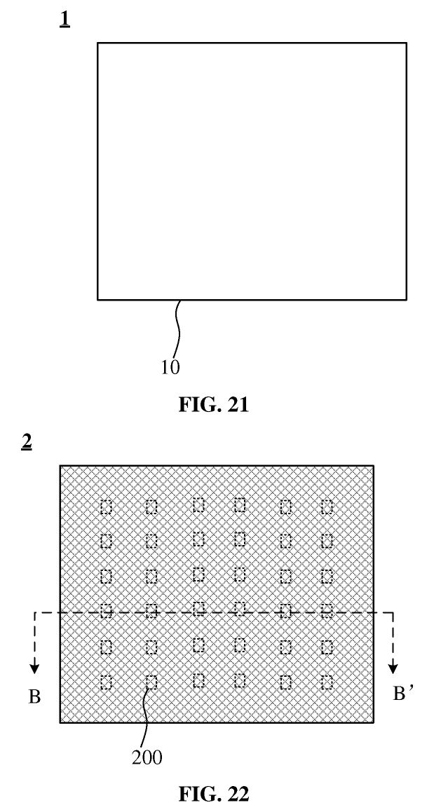

Based on the same inventive concept, an embodiment of the present application also provides a backlight module. FIG. 21 is a structural view of a backlight module according to an embodiment of the present application. As shown in FIG. 21, the backlight module 1 includes the light-emitting panel assembly 10 in any embodiments of the present application. The backlight module 1 provided in this embodiment of the present application has the beneficial effects described in any preceding embodiment. The same or corresponding structure and the explanation of terms as those in the preceding embodiments are not repeated here.

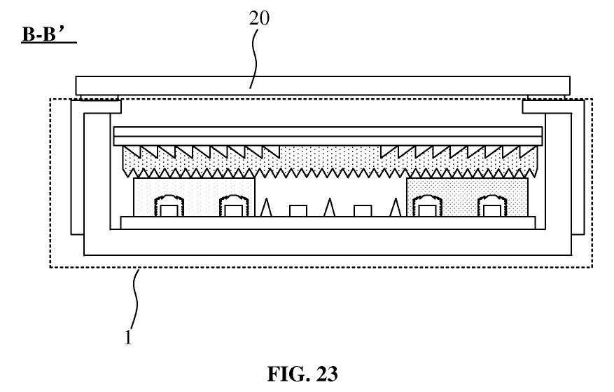

Based on the same inventive concept, an embodiment of the present application further provides a display device. FIG. 22 is a structural view of a display device according to an embodiment of the present application. FIG. 23 is a sectional view taken along line B-B' of FIG. 22. Referring to FIGS. 22 and 23, the display device 2 includes the backlight module 1 in any preceding embodiment and a display panel 20 located on a side of the light emission surface of the backlight module 1. Therefore, the display device 1 provided in this embodiment of the present application also has the beneficial effects described in the preceding embodiments, which is not repeated here. The display device 1 may be, for example, a mobile phone, a computer, a smart wearable device (such as a smartwatch), or an in-vehicle display device.

Apparently, the preceding embodiments of the present application are merely examples to illustrate the present application and are not intended to limit embodiments of the present application. And those skilled in the art can make various apparent modifications, adaptations and substitutions without departing from the scope of the present application. Embodiments of the present application cannot be and do not need to be exhausted herein. Any modifications, equivalent substitutions and improvements within the spirit and principle of the present application fall within the scope of the claims of the present application.

What is claimed is:

1. A light-emitting panel, comprising:
a first light-emitting region and a second light-emitting region, wherein the first light-emitting region is located on a side of the second light-emitting region facing an edge of the light-emitting panel, and the first light-emitting region is provided with a plurality of first light-emitting elements; and
a light emission adjustment structure, wherein the light emission adjustment structure is located on a light emission side of the plurality of first light-emitting elements, and a surface of the light emission adjustment structure facing the plurality of first light-emitting elements is non-planar.

2. The light-emitting panel according to claim 1, wherein the light emission adjustment structure comprises a first light emission adjustment structure, the first light emission adjustment structure comprises a plurality of first avoidance recesses, and a first avoidance recess among the plurality of first avoidance recesses covers at least one first light-emitting element among the plurality of first light-emitting elements.

3. The light-emitting panel according to claim 2, wherein the first avoidance recess comprises an inner surface, and at least part of the inner surface is provided with a Fresnel lens.

4. The light-emitting panel according to claim 3, further comprising a driving substrate, wherein the first light-emitting element is disposed on a side of the driving substrate and is electrically connected to the driving substrate;
the first light-emitting element comprises an upper light-emitting surface, and the upper light-emitting surface is a light-emitting surface of the first light-emitting element facing away from the driving substrate; and
the inner surface comprises an upper inner surface located on a side of the upper light-emitting surface facing away from the driving substrate, and the upper inner surface is provided with a first Fresnel lens.

5. The light-emitting panel according to claim 4, wherein the first light-emitting element further comprises a side light-emitting surface, and the side light-emitting surface is connected to the upper light-emitting surface;
the inner surface further comprises a side inner surface, and the side inner surface is connected to the upper inner surface and is located on a side of the side light-emitting surface; and
the side inner surface is provided with a second Fresnel lens.

6. The light-emitting panel according to claim 5, wherein the side light-emitting surface comprises a first side light-emitting surface and a second side light-emitting surface, and the first side light-emitting surface is located on a side of the second side light-emitting surface facing the edge of the light-emitting panel;
the side inner surface comprises a first side inner surface and a second side inner surface, the first side inner surface is located on a side of the first side light-emitting surface facing the edge of the light-emitting panel, and the second side inner surface is located on a side of the second side light-emitting surface facing away from the edge of the light-emitting panel; and
the first side inner surface and the second side inner surface are each provided with a second Fresnel lens, and distribution density of Fresnel rings in a second Fresnel lens on the first side inner surface is greater than or equal to distribution density of Fresnel rings in a second Fresnel lens on the second side inner surface.

7. The light-emitting panel according to claim 5, wherein at least one of the following is satisfied:
distribution density of Fresnel rings in the first Fresnel lens is greater than or equal to distribution density of Fresnel rings in the second Fresnel lens;
a minimum distance between the upper light-emitting surface and the upper inner surface is less than or equal to a minimum distance between the side light-emitting surface and the side inner surface; or
the first Fresnel lens and the second Fresnel lens are disposed independently.

8. The light-emitting panel according to claim 5, wherein the plurality of first light-emitting elements comprise a first light-emitting sub-element and a second light-emitting sub-element, and the first light-emitting sub-element is located on a side of the second light-emitting sub-element facing the edge of the light-emitting panel;
the first light emission adjustment structure comprises a first inner surface and a second inner surface, wherein the first inner surface at least partially covers the first light-emitting sub-element, and the second inner surface at least partially covers the second light-emitting sub-element; and
the first inner surface comprises a first upper inner surface and a third side inner surface, and the second inner surface comprises a second upper inner surface and a fourth side inner surface;
wherein at least one of the following is satisfied: distribution density of Fresnel rings in a first Fresnel lens on the first upper inner surface is greater than or equal to distribution density of Fresnel rings in a first Fresnel lens on the second upper inner surface; or distribution density of Fresnel rings in a second Fresnel lens on the third side inner surface is greater than or equal to distribution density of Fresnel rings in a second Fresnel lens on the fourth side inner surface.

9. The light-emitting panel according to claim 5, wherein the plurality of first light-emitting elements comprise a first light-emitting sub-element and a second light-emitting sub-element, the first light-emitting sub-element is located on a side of the second light-emitting sub-element facing the edge of the light-emitting panel, the first light-emitting sub-element comprises a first upper light-emitting surface and a third side light-emitting surface, and the second light-emitting sub-element comprises a second upper light-emitting surface and a fourth side light-emitting surface; and
the first light emission adjustment structure comprises a first inner surface and a second inner surface, wherein the first inner surface at least partially covers the first light-emitting sub-element, and the second inner surface at least partially covers the second light-emitting sub-element; the first inner surface comprises a first upper inner surface and a third side inner surface; and the second inner surface comprises a second upper inner surface and a fourth side inner surface;
wherein at least one of the following is satisfied: a minimum distance between the first upper inner surface and the first upper light-emitting surface is less than or equal to a minimum distance between the second upper inner surface and the second upper light-emitting surface; or a minimum distance between the third side inner surface and the third side light-emitting surface is less than or equal to a minimum distance between the fourth side inner surface and the fourth side light-emitting surface.

10. The light-emitting panel according to claim 3, further comprising a plurality of second light-emitting elements disposed in the second light-emitting region; and a plurality of reflective units, wherein the plurality of reflective units comprise a first reflective unit and a second reflective unit, the first reflective unit is disposed in the first light-emitting region and located between two adjacent ones of the plurality of first light-emitting elements, and the second reflective unit is disposed in the second light-emitting region and located between two adjacent ones of the plurality of second light-emitting elements; and
wherein at least one of the following is satisfied:
a height of the first reflective unit is greater than a height of the second reflective unit in a light emission direction of the plurality of first light-emitting elements; or
the first light emission adjustment structure further comprises a plurality of second avoidance recesses, and a second avoidance recess among the plurality of second avoidance recesses covers the first reflective unit.

11. The light-emitting panel according to claim 3, wherein at least one of the following is satisfied:
a surface of the first light emission adjustment structure facing away from the plurality of first light-emitting elements comprises a plane; or
a distance L between two adjacent ones of the plurality of first light-emitting elements satisfies that L ≤ 6 mm.

12. The light-emitting panel according to claim 1, wherein the light emission adjustment structure comprises a second light emission adjustment structure; and the second light emission adjustment structure comprises a light entry adjustment surface facing the plurality of first light-emitting elements and a light emission adjustment surface facing away from the plurality of first light-emitting elements;
the light entry adjustment surface comprises a first light entry adjustment surface portion; the light emission adjustment surface comprises a first light emission adjustment surface portion; in a light emission direction of the plurality of first light-emitting elements, the first light entry adjustment surface portion covers at least one of the plurality of first light-emitting elements; and the first light emission adjustment surface portion at least partially overlaps the first light entry adjustment surface portion; and
the first light entry adjustment surface portion is provided with a plurality of inversing prisms, and the first light emission adjustment surface portion is provided with a plurality of right-angle prisms.

13. The light-emitting panel according to claim 12, wherein at least one of the following is satisfied:
the plurality of inversing prisms extend in a first direction and are arranged in a second direction; and the plurality of right-angle prisms extend in the first direction and are arranged in the second direction, the first direction intersects with the second direction, and both the first direction and the second direction intersect with the light emission direction of the plurality of first light-emitting elements;
a sectional shape of an inversing prism among the plurality of inversing prisms is an isosceles triangle, an angle between a first leg in the isosceles triangle and a second leg in the isosceles triangle is a first vertex angle, the first vertex angle faces a side of one of the plurality of first light-emitting elements, and the first vertex angle is in a range of 80° to 100°; and a sectional shape of a right-angle prism among the plurality of right-angle prisms is a right triangle, an angle between a first right-angle side in the right triangle and a hypotenuse in the right triangle is a second vertex angle, the second vertex angle faces away from a side of one of the plurality of first light-emitting elements, and the second vertex angle is in a range of 60° to 75°; or
a distance L between two adjacent ones of the plurality of first light-emitting elements satisfies that L > 6 mm.

14. The light-emitting panel according to claim 12, wherein at least one of the following is satisfied:
the first light entry adjustment surface portion comprises a first light entry adjustment region and a second light entry adjustment region; the first light entry adjustment region is located on a side of the second light entry adjustment region facing the edge of the light-emitting panel; and distribution density of inversing prisms in the first light entry adjustment region is greater than or equal to distribution density of inversing prisms in the second light entry adjustment region, wherein both the inversing prisms in the first light entry adjustment region and the inversing prisms in the second light entry adjustment region are among the plurality of inversing prisms; or
the first light emission adjustment surface portion comprises a first light emission adjustment region and a second light emission adjustment region; the first light emission adjustment region is located on a side of the second light emission adjustment region facing the edge of the light-emitting panel; and distribution density of right-angle prisms in the first light emission adjustment region is greater than or equal to distribution density of right-angle prisms in the second light emission adjustment region, wherein both the right-angle prisms in the first light emission adjustment region and the right-angle prisms in the second light emission adjustment region are among the plurality of right-angle prisms.

15. The light-emitting panel according to claim 12, further comprising a plurality of second light-emitting elements disposed in the second light-emitting region;
the light entry adjustment surface comprises a second light entry adjustment surface portion; the light emission adjustment surface comprises a second light emission adjustment surface portion; in a light emission direction of the plurality of second light-emitting elements, the second light entry adjustment surface portion covers at least one of the plurality of second light-emitting elements; and the second light emission adjustment surface portion at least partially overlaps the second light entry adjustment surface portion; and
the second light entry adjustment surface portion is provided with a plurality of inversing prisms, and the second light emission adjustment surface portion comprises a plane.

16. The light-emitting panel according to claim 1, wherein the light emission adjustment structure comprises a first light emission adjustment structure and a second light emission adjustment structure;
the first light emission adjustment structure comprises a plurality of first avoidance recesses, and a first avoidance recess among the plurality of first avoidance recesses covers at least one first light-emitting element among the plurality of first light-emitting elements;
the first avoidance recess comprises an inner surface, and at least part of the inner surface is provided with a Fresnel lens;
the second light emission adjustment structure is located on a side of the first light emission adjustment structure facing away from the plurality of first light-emitting elements; and the second light emission adjustment structure comprises a light entry adjustment surface facing the plurality of first light-emitting elements and a light emission adjustment surface facing away from the plurality of first light-emitting elements;
the light entry adjustment surface comprises a first light entry adjustment surface portion; the light emission adjustment surface comprises a first light emission adjustment surface portion; in a light emission direction of the plurality of first light-emitting elements, the first light entry adjustment surface portion covers at least one of the plurality of first light-emitting elements; and the first light emission adjustment surface portion at least partially overlaps the first light entry adjustment surface portion; and
the first light entry adjustment surface portion is provided with a plurality of inversing prisms, and the first light emission adjustment surface portion is provided with a plurality of right-angle prisms.

17. The light-emitting panel according to claim 16, wherein at least one of the following is satisfied:
in the light emission direction of the plurality of first light-emitting elements, the first light entry adjustment surface portion covers the first light emission adjustment structure, and the first light emission adjustment surface portion covers the first light emission adjustment structure; or
the first light emission adjustment structure is in contact with the second light emission adjustment structure, and an end portion of the first light entry adjustment surface portion facing the edge of the light-emitting panel is suspended.

18. The light-emitting panel according to claim 1, further comprising a plurality of second light-emitting elements disposed in the second light-emitting region; and
a driving substrate electrically connected to the plurality of first light-emitting elements and the plurality of second light-emitting elements for supplying drive signals to the plurality of first light-emitting elements and the plurality of second light-emitting elements; wherein
drive signals of at least part of the plurality of first light-emitting elements are greater than drive signals of at least part of the plurality of second light-emitting elements.

19. A backlight module, comprising a light-emitting panel, wherein the light-emitting panel comprises:
a first light-emitting region and a second light-emitting region, wherein the first light-emitting region is located on a side of the second light-emitting region facing an edge of the light-emitting panel, and the first light-emitting region is provided with a plurality of first light-emitting elements; and
a light emission adjustment structure, wherein the light emission adjustment structure is located on a light emission side of the plurality of first light-emitting elements, and a surface of the light emission adjustment structure facing the plurality of first light-emitting elements is non-planar.

20. A display device, comprising a backlight module and a display panel located on a side of a light emission surface of the backlight module;
wherein the backlight module comprises a light-emitting panel, wherein the light-emitting panel comprises:
a first light-emitting region and a second light-emitting region, wherein the first light-emitting region is located on a side of the second light-emitting region facing an edge of the light-emitting panel, and the first light-emitting region is provided with a plurality of first light-emitting elements; and
a light emission adjustment structure, wherein the light emission adjustment structure is located on a light emission side of the plurality of first light-emitting elements, and a surface of the light emission adjustment structure facing the plurality of first light-emitting elements is non-planar.
